(19) United States
(12) Patent Application Publication
(10) Pub. No.: US 2024/0338017 A1
(43) Pub. Date: Oct. 10, 2024

(54) INFORMATION PROCESSING DEVICE, INFERENCE DEVICE, AND MACHINE LEARNING DEVICE

(71) Applicant: EBARA CORPORATION, Tokyo (JP)

(72) Inventors: CHING WEI HUANG, Tokyo (JP); HIROFUMI OTAKI, Tokyo (JP); TAKAMASA NAKAMURA, Tokyo (JP)

(73) Assignee: EBARA CORPORATION, Tokyo (JP)

(21) Appl. No.: 18/624,160

(22) Filed: Apr. 2, 2024

(30) Foreign Application Priority Data
Apr. 5, 2023 (JP) 2023-061606

(51) Int. Cl. G05B 19/418; H01L 21/67

(52) U.S. Cl. CPC G05B 19/4189; H01L 21/67253; G05B 2219/45031

(57) ABSTRACT

An information processing device includes: a target processing quantity reception part that receives a target processing quantity of substrates per unit time of a time when a processing action repeating a substrate processing and a transport processing on substrates is performed in a substrate processing apparatus; a device information acquisition part that acquires device information including transport processing information defining an action state of the transport processing of the time when the processing action is performed; and a support information generation part that generates support information including a recipe available time which is available for the substrate processing based on the target processing quantity and the device information.

### CROSS-REFERENCE TO RELATED APPLICATION

This application claims the priority benefit of Japan application serial no. 2023-061606, filed on Apr. 5, 2023. The entirety of the above-mentioned patent application is hereby incorporated by reference herein and made a part of this specification.

### BACKGROUND

### Technical Field

The disclosure relates to an information processing device, an inference device, a machine learning device, an information processing method, an inference method, and a machine learning method.

### Related Art

One of substrate processing apparatuses that perform various substrate processings on substrates such as semiconductor wafers is a substrate processing apparatus that performs chemical-mechanical polishing (CMP). Such a substrate processing apparatus includes, for example, a polishing unit that performs a polishing processing on the substrate, a finishing unit that performs a finishing processing (e.g., a washing processing and a drying processing) on the substrate after the polishing processing, and a transport unit that performs a transport processing of transporting the substrate between each unit. The substrate processing apparatus is configured to perform a series of processings by causing each unit to act sequentially (e.g., see Patent Document 1: Japanese Patent Application Laid-Open No. 2007-301690).

A target processing quantity of substrates per unit time (so-called a target value of WPH) is used as an indicator when managing the operation of the substrate processing apparatus. The processing content of the substrate processing performed in the substrate processing unit such as the polishing unit and the finishing unit is defined by recipe information, so the substrate processing time required for the substrate processing changes depending on the setting of the recipe information, which affects achievement of the target processing quantity. In particular, to improve the processing performance (quality of the substrate surface and the like) of the substrate processing, there is a tendency for the substrate processing time to increase. At that time, in the operation of the substrate processing apparatus, not only is the substrate processing performed in the substrate processing unit, but a transport processing is also performed in the transport processing unit. Thus, to achieve the target processing quantity and improve the processing performance of the substrate processing, it is difficult to identity how much time is available for the substrate processing performed according to the recipe information.

### SUMMARY

An information processing device according to an aspect of the disclosure is an information processing device supporting an operation of a substrate processing apparatus. The substrate processing apparatus includes: a substrate processing unit that performs a substrate processing on a substrate according to recipe information indicating a processing content of the substrate processing; and a transport processing unit that performs a transport processing of transporting the substrate before the substrate processing and after the substrate processing. The information processing device includes a target processing quantity reception part, a device information acquisition part, and a support information generation part. The target processing quantity reception part receives a target processing quantity of the substrate per unit time of a time when a processing action repeating the substrate processing and the transport processing on a plurality of substrates is performed in the substrate processing apparatus. The device information acquisition part acquires device information including transport processing information which defines an action state of the transport processing of the time when the processing action is performed. The support information generation part generates support information including a recipe available time which is available for the substrate processing performed according to the recipe information, based on the target processing quantity received by the target processing quantity reception part and the device information acquired by the device information acquisition part.

According to the information processing device according to an aspect of the disclosure, based on the target processing quantity of substrates per unit time and the device information including the transport processing information defining the action state of the transport processing, the support information generation part generates the support information including the recipe available time that is available for the substrate processing performed according to the recipe information. Thus, when setting the recipe information, since the recipe available time that is available for the substrate processing can be identified in advance, the setting of the recipe information can be appropriately supported.

Other aspects of the disclosure will be illustrated in the embodiments for carrying out the disclosure to be described later.

### BRIEF DESCRIPTION OF DRAWINGS

FIG. 1 is an overall configuration view showing an example of a substrate processing system 1 according to a first embodiment.

FIG. 2 is a schematic plan view showing an example of a substrate processing apparatus 2.

FIG. 3 is a schematic view showing an example of a transport route (first half) of a wafer W in the substrate processing apparatus 2.

FIG. 4 is a schematic view showing an example of a transport route (second half) of the wafer W in the substrate processing apparatus 2.

FIG. 5 is a perspective view showing an example of first to fourth polishing units 22A to 22D.

FIG. 6 is a perspective view showing an example of first finishing units 230A and 230B which perform a roll sponge washing processing.

FIG. 7 is a perspective view showing an example of second finishing units 231A and 231B which perform a pen sponge washing processing.

FIG. 8 is a perspective view showing an example of third finishing units 232A and 232B which perform a drying processing.

FIG. 9 is a schematic side view showing an example of a substrate transport part 24 (second transport units 241A and 241B and transfer robot 243).

FIG. 10 is a schematic side view showing an example of the substrate transport part 24 (third transport units 242A and 242B and transfer robot 243).

FIG. 11 is a block diagram showing an example of the substrate processing apparatus 2.

FIG. 12 is a hardware configuration view showing an example of a computer 900.

FIG. 13 is a block diagram showing an example of an information processing device 3A according to the first embodiment.

FIG. 14 is a function illustrative view showing an example of the information processing device 3A according to the first embodiment.

FIG. 15 is a view showing a calculation example of a recipe available time TRPW1 for a polishing processing PP.

FIG. 16 is a view showing a calculation example of a recipe available time TRPW2 for a finishing processing PC.

FIG. 17 is a flowchart showing an example of an information processing method performed by the information processing device 3A according to the first embodiment.

FIG. 18 is a block diagram showing an example of an information processing device 3B according to a second embodiment.

FIG. 19 is a function illustrative view showing an example of the information processing device 3B according to the second embodiment.

FIG. 20 is a view showing an example of learning data 15 and a learning model 16.

FIG. 21 is a flowchart showing an example of a machine learning method performed by a machine learning device 5.

FIG. 22 is a flowchart showing an example of an information processing method performed by the information processing device 3B according to the second embodiment.

### DESCRIPTION OF EMBODIMENTS

Embodiments of the disclosure provide an information processing device, an inference device, a machine learning device, an information processing method, an inference method, and a machine learning method capable of supporting setting of recipe information that defines a processing content of a substrate processing in a substrate processing apparatus.

Hereinafter, embodiments for carrying out the disclosure will be described with reference to the drawings. In the following, a range necessary for descriptions for achieving the objective of the disclosure will be schematically illustrated, a range necessary for descriptions of the relevant portion of the disclosure will be mainly described, and parts for which descriptions are omitted will be regarded as based on the conventional art.

### First Embodiment

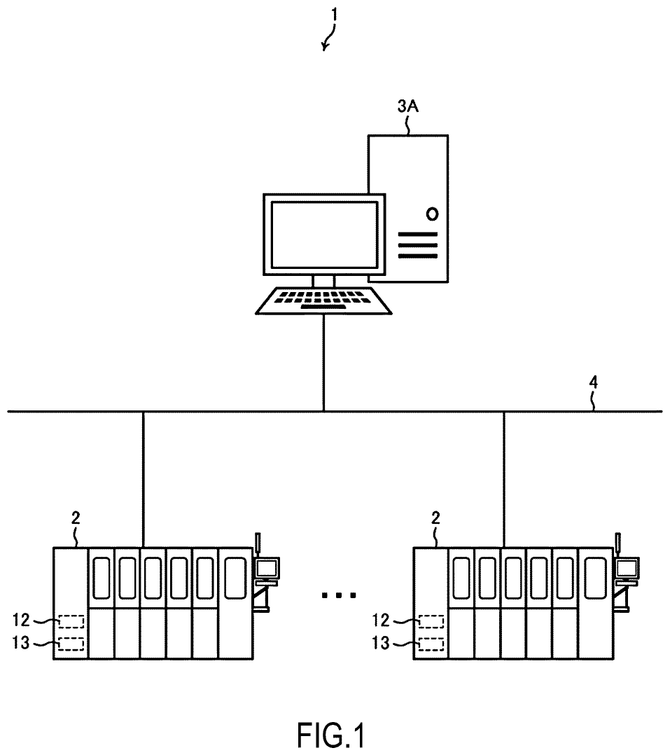

FIG. 1 is an overall configuration view showing an example of a substrate processing system 1 according to a first embodiment. The substrate processing system 1 according to this embodiment includes a substrate processing apparatus 2 and an information processing device 3A as main components, and is configured to be connected to a wired or wireless network 4 to be capable of sending and receiving various data to each other. The quantities of the substrate processing apparatus 2 and the information processing device 3A and the connection configuration of the network 4 are not limited to the example in FIG. 1 and may be changed as appropriate.

The substrate processing apparatus 2 includes a substrate processing unit (to be described in detail later) that performs various substrate processings on a substrate (hereinafter referred to as a “wafer”) W such as a semiconductor wafer, and a transport processing unit (to be described in detail later) that transports the wafer W. In this embodiment, the substrate processing apparatus 2 includes a polishing unit and a finishing unit as the substrate processing unit, and performs a chemical-mechanical polishing processing (hereinafter referred to as a “polishing processing”), a finishing processing, a transport processing, etc. on the wafer W by causing the polishing unit, the finishing unit, and the transport processing unit to act. At that time, the substrate processing apparatus 2 controls actions of the polishing unit, the finishing unit, and the transport processing unit while referring to device setting information 12 that is composed of a plurality of device parameters set respectively in the polishing unit, the finishing unit, and the transport processing unit, and recipe information 13 that defines processing contents of the polishing processing and the finishing processing.

The information processing device 3A is a terminal device used by a user and is composed of a stationary or portable device. For example, the information processing device 3A receives various input operations via a display screen of an application program, a web browser, etc. and displays various information via the display screen.

The information processing device 3A is a device that supports the operation of the substrate processing apparatus 2 by performing setting of the device setting information 12 and the recipe information 13, formulation of an operation plan of the substrate processing apparatus 2, confirmation of operation results, etc. In particular, the information processing device 3A generates support information (to be described in detail later) for supporting the setting operation of the recipe information 13 and provides the support information to the user. The information processing device 3A may be composed of a server-type or cloud-type device, and in that case, the information processing device 3A may act in cooperation with a user terminal device (not shown) on a client side.

### Substrate Processing Apparatus

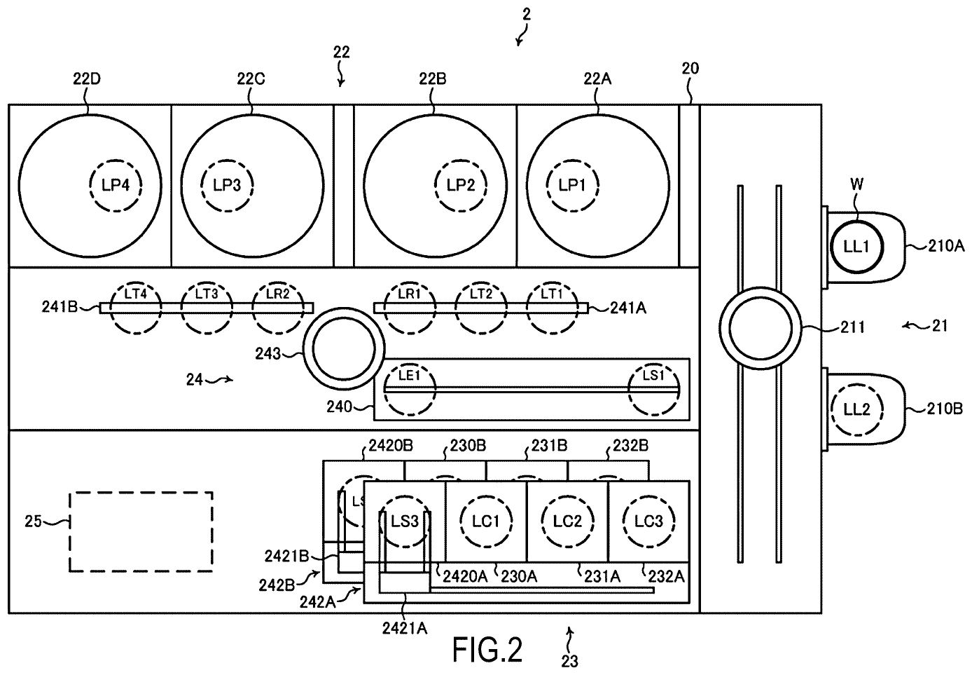

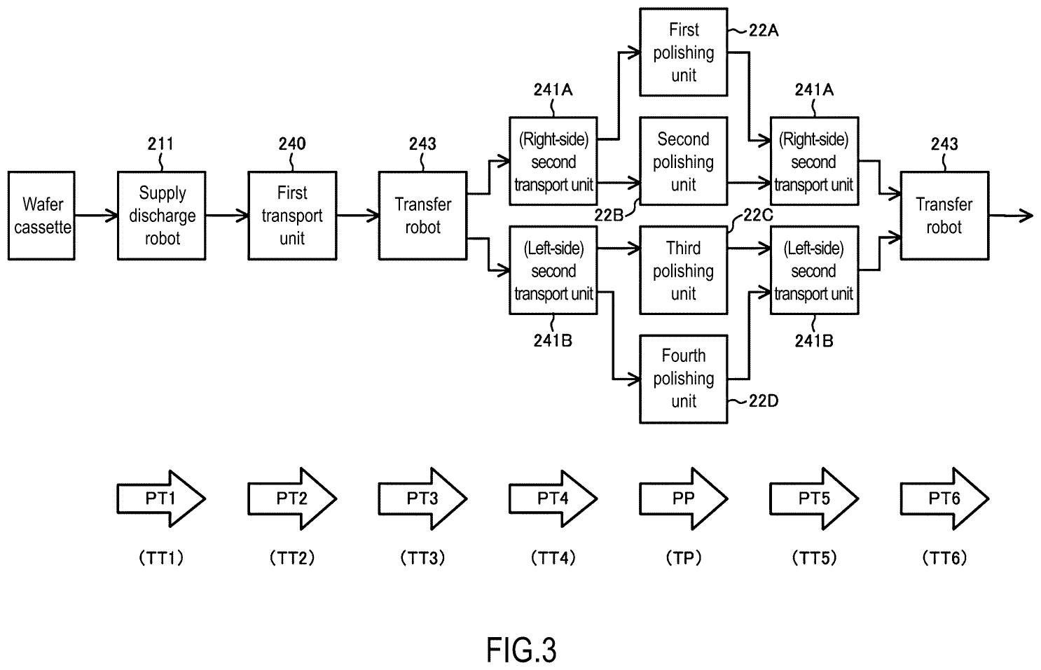

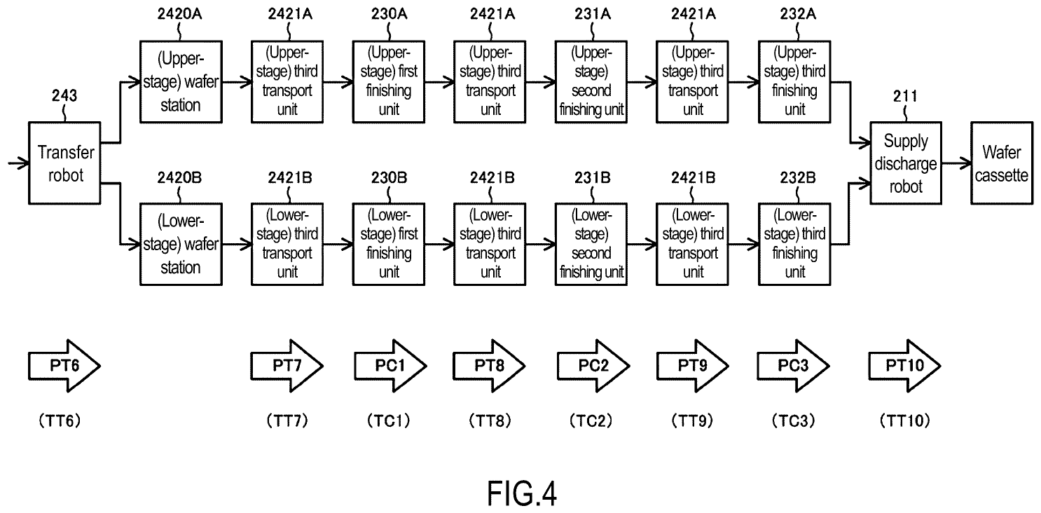

FIG. 2 is a schematic plan view showing an example of the substrate processing apparatus 2. FIG. 3 and FIG. 4 are schematic views showing an example of a transport route of the wafer W in the substrate processing apparatus 2. The substrate processing apparatus 2 is configured to include a load/unload part 21, a polishing part 22, a finishing part 23, a substrate transport part 24, and a control unit 25, inside a housing 20 in a substantially rectangular shape in a plan view.

### Load/Unload Part

The load/unload part 21 includes first and second front load parts 210A and 210B on which wafer cassettes (substrate cassettes such as FOUPs) capable of storing a large number of wafers W in the up-down direction are placed at wafer cassette positions LL1 and LL2, and a supply discharge robot 211 that performs supply and discharge of the wafer W.

The supply discharge robot 211 is configured to be movable in the horizontal direction along the short-side direction of the housing 20, and is configured to be movable in the up-down direction and the turning direction. The supply discharge robot 211 includes upper and lower hands (not shown) in two stages for handing over the wafer W. One of the hands is used when handing over a wafer W before the polishing processing, and the other of the hands is used when handing over a wafer W after the finishing processing. For example, the hands are configured to be extendable and capable of flipping the wafer W upside down.

As a transport processing PT of the wafer W, the supply discharge robot 211 performs a substrate supply processing PT1 of taking out a wafer W before the polishing processing from the wafer cassette and supplying the wafer W to a first transport unit 240, and a substrate discharge processing PT10 of receiving a wafer W after the finishing processing from the finishing part 23 (in this embodiment, third finishing units 232A and 232B) and storing the wafer W to the wafer cassette.

### Polishing Part

The polishing part 22 includes a plurality (four in this embodiment) of polishing units 22A to 22D that respectively perform a polishing processing PP on the wafer W. In this embodiment, the first to fourth polishing units 22A to 22D are arranged side by side along the long-side direction of the housing 20 and perform the polishing processing PP on the wafer W in parallel at polishing positions LP1 to LP4. The first to fourth polishing units 22A to 22D are configured to be accessible at polishing unit handover positions LT1 to LT4 for handing over the wafer W. The polishing unit handover positions LT1 to LT4 are individually set for the first to fourth polishing units 22A to 22D.

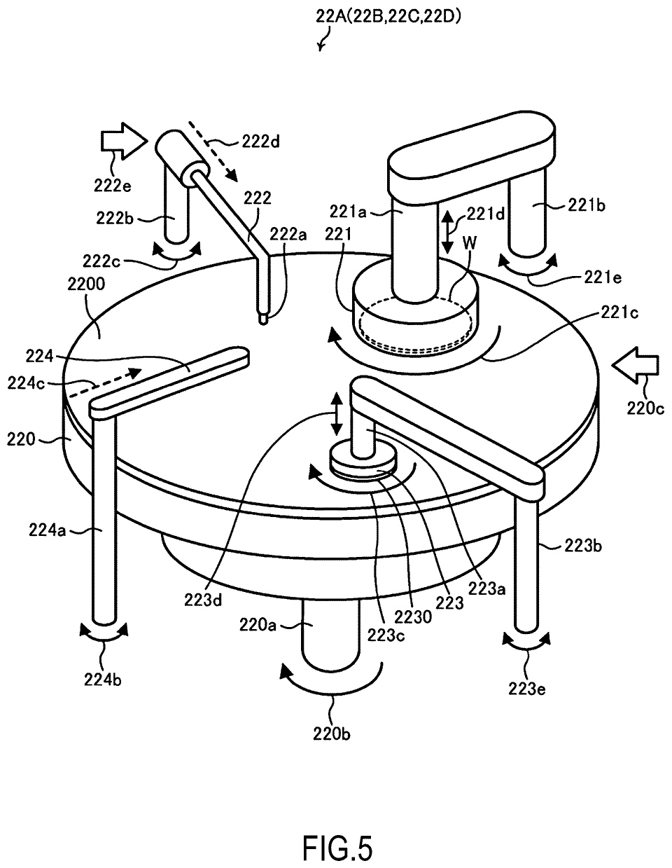

FIG. 5 is a perspective view showing an example of the first to fourth polishing units 22A to 22D. In this embodiment, the basic configuration and function of the first to fourth polishing units 22A to 22D will be described as common among each other.

Each of the first to fourth polishing units 22A to 22D includes a polishing table 220 that rotatably supports a polishing pad 2200 having a polishing surface, a top ring (substrate holding part) 221 that rotatably holds the wafer W and polishes the wafer W while pressing the wafer W against the polishing pad 2200 on the polishing table 220, a polishing fluid supply part 222 that supplies a polishing fluid to the polishing pad 2200, a dresser 223 that rotatably supports a dresser disk 2230 and causes the dresser disk 2230 to contact the polishing surface of the polishing pad 2200 to dress the polishing pad 2200, and an atomizer 224 that sprays a washing fluid to the polishing pad 2200.

The polishing table 220 includes a rotational movement mechanism part 220b that is supported by a polishing table shaft 220a and rotationally drives the polishing table 220 around its axis, and a temperature adjustment mechanism part 220c that adjusts the surface temperature of the polishing pad 2200.

The top ring 221 includes a rotational movement mechanism part 221c that is supported by a top ring shaft 221a movable in the up-down direction and rotationally drives the top ring 221 around its axis, an up-down movement mechanism part 221d that causes the top ring 221 to move in the up-down direction, and a swinging movement mechanism part 221e that causes the top ring 221 to turn (swing) around a support shaft 221b as a center of turning. The rotational movement mechanism part 221c, the up-down movement mechanism part 221d, and the swinging movement mechanism part 221e function as substrate movement mechanism parts that cause movement of the relative position between the polishing pad 2200 and the polished surface of the wafer W.

The polishing fluid supply part 222 includes a polishing fluid supply nozzle 222a that supplies a polishing fluid to the polishing surface of the polishing pad 2200, a swinging movement mechanism part 222c that is supported by a support shaft 222b and causes the polishing fluid supply nozzle 222a to turn and move around the support shaft 222b as a center of turning, a flow rate adjustment part 222d that adjusts the flow rate of the polishing fluid, and a temperature adjustment mechanism part 222e that adjusts the temperature of the polishing fluid. The polishing fluid may be a polishing liquid (slurry) or pure water, and may further contain a chemical solution, or a dispersant may be added to the polishing liquid.

The dresser 223 includes a rotational movement mechanism part 223c that is supported by a dresser shaft 223a movable in the up-down direction and rotationally drives the dresser 223 around its axis, an up-down movement mechanism part 223d that causes the dresser 223 to move in the up-down direction, and a swinging movement mechanism part 223e that causes the dresser 223 to turn and move around a support shaft 223b as a center of turning.

The atomizer 224 includes a swinging movement mechanism part 224b that is supported by a support shaft 224a and causes the atomizer 224 to turn and move around the support shaft 224a as a center of turning, and a flow rate adjustment part 224c that adjusts the flow rate of the washing fluid. The washing fluid is a mixed fluid of a liquid (e.g., pure water) and a gas (e.g., nitrogen gas) or is a liquid (e.g., pure water).

In the polishing processing PP, by moving the top ring 221 to the polishing unit handover positions LT1 to LT4 and adsorbing and holding the wafer W before the polishing processing onto the lower surface of the top ring 221, the wafer W before the polishing processing is received from second transport units 241A and 241B. Then, by moving the top ring 221 to the polishing positions LP1 to LP4 on the polishing table 220 and pressing the wafer W against the polishing surface of the polishing pad 2200 to which the polishing fluid has been supplied from the polishing fluid supply nozzle 222a, the wafer W is polished. When the polishing processing PP ends, the top ring 221 moves to the polishing unit handover positions LT1 to LT4 and hands over the wafer W after the polishing processing to the second transport units 241A and 241B.

### Finishing Part

The finishing part 23 includes a plurality (in this embodiment, six with three types each arranged in upper and lower (two) stages) of finishing units 230A to 232A and 230B to 232B that respectively perform a finishing processing PC on the wafer W. In this embodiment, the first to third finishing units 230A to 232A are arranged in the upper stage side by side along the long-side direction of the housing 20, and the first to third finishing units 230B to 232B having the same configuration are arranged in the lower stage side by side along the long-side direction of the housing 20. The first to third finishing units 230A to 232A and 230B to 232B respectively perform the finishing processing PC in their arrangement sequence (finishing process sequence) at finishing positions LC1 to LC3.

As the finishing processing PC of a most upstream process, the first finishing units 230A and 230B perform a roll sponge washing processing (first finishing processing PC1) of washing the wafer W after the polishing processing using a roll sponge 2300. The second finishing units 231A and 231B perform a pen sponge washing processing (second finishing processing PC2) of washing the wafer W after the roll sponge washing processing using a pen sponge 2310. As the finishing processing PC of a most downstream process, the third finishing units 232A and 232B perform a drying processing (third finishing processing PC3) of drying the wafer W after the pen sponge washing processing. The finishing processing PC may also start with, for example, the pen sponge washing processing, omitting the roll sponge washing processing.

Instead of or in addition to any of the first and second finishing units 230A, 230B, 231A, and 231B, the finishing part 23 may also include a finishing unit (not shown) that performs a buff washing processing of washing the wafer W using a buff, and any of the first and second finishing units 230A, 230B, 231A, and 231B may be omitted. Further, in this embodiment, although the first to third finishing units 230A to 232A and 230B to 232B have been described as holding the wafer W in a horizontal position (horizontal holding), they may also hold the wafer W in a vertical or oblique position.

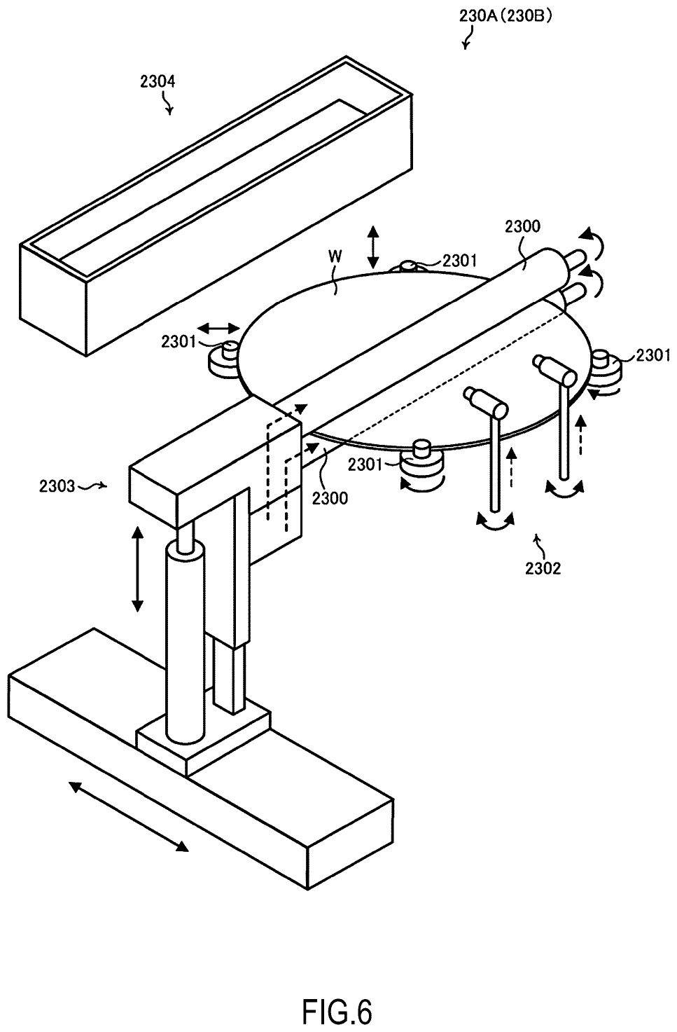

FIG. 6 is a perspective view showing an example of the first finishing units 230A and 230B which perform the roll sponge washing processing. The first finishing units 230A and 230B include a substrate holding part 2301 that holds the wafer W, a washing fluid supply part 2302 that supplies a substrate washing fluid to the wafer W, a substrate washing part 2303 that rotatably supports the roll sponge 2300 and causes the roll sponge 2300 to contact the wafer W to wash the wafer W, and a washing tool washing part 2304 that washes (self-cleans) the roll sponge 2300 with a washing tool washing fluid. The substrate washing fluid may be any of pure water (rinse liquid) and a chemical solution, and may be a liquid or a two-fluid mixture of a liquid and a gas, or may contain a solid such as dry ice. The washing tool washing fluid may be any of pure water (rinse liquid) and a chemical solution.

In the roll sponge washing processing performed by the first finishing units 230A and 230B, the wafer W is rotated in a state held at the first finishing position LC1 by the substrate holding part 2301. Then, with the substrate washing fluid supplied to the washed surface of the wafer W from the washing fluid supply part 2302, the wafer W is washed by slidably contacting the roll sponge 2300, which is rotated around its axis by the substrate washing part 2303, with the washed surface of the wafer W.

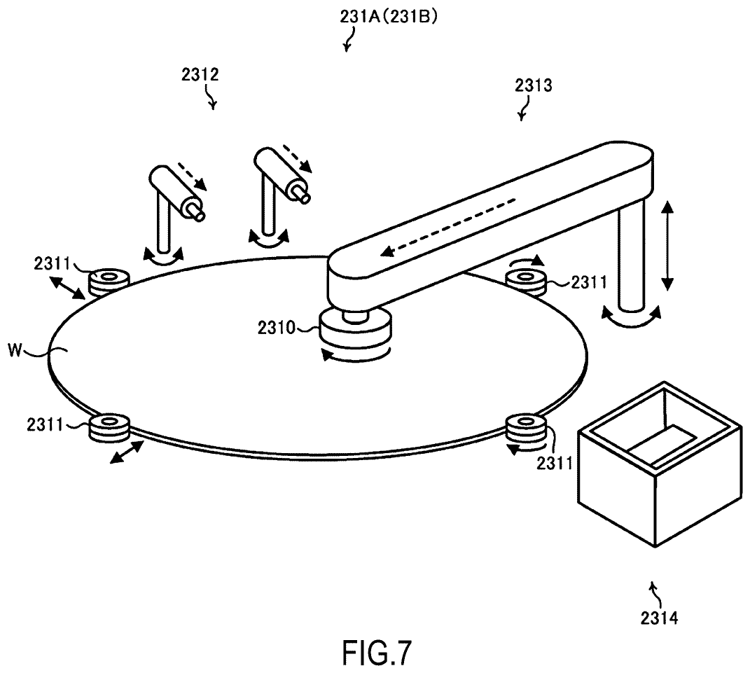

FIG. 7 is a perspective view showing an example of the second finishing units 231A and 231B which perform the pen sponge washing processing. The second finishing units 231A and 231B include a substrate holding part 2311 that holds the wafer W, a washing fluid supply part 2312 that supplies a substrate washing fluid to the wafer W, a substrate washing part 2313 that rotatably supports the pen sponge 2310 and causes the pen sponge 2310 to contact the wafer W to wash the wafer W, and a washing tool washing part 2314 that washes (self-cleans) the pen sponge 2310 with a washing tool washing fluid.

In the pen sponge washing processing performed by the second finishing units 231A and 231B, the wafer W is rotated in a state held at the second finishing position LC2 by the substrate holding part 2311. Then, with the substrate washing fluid supplied to the washed surface of the wafer W from the washing fluid supply part 2312, the wafer W is washed by slidably contacting the pen sponge 2310, which is rotated around its axis by the substrate washing part 2313, with the washed surface of the wafer W.

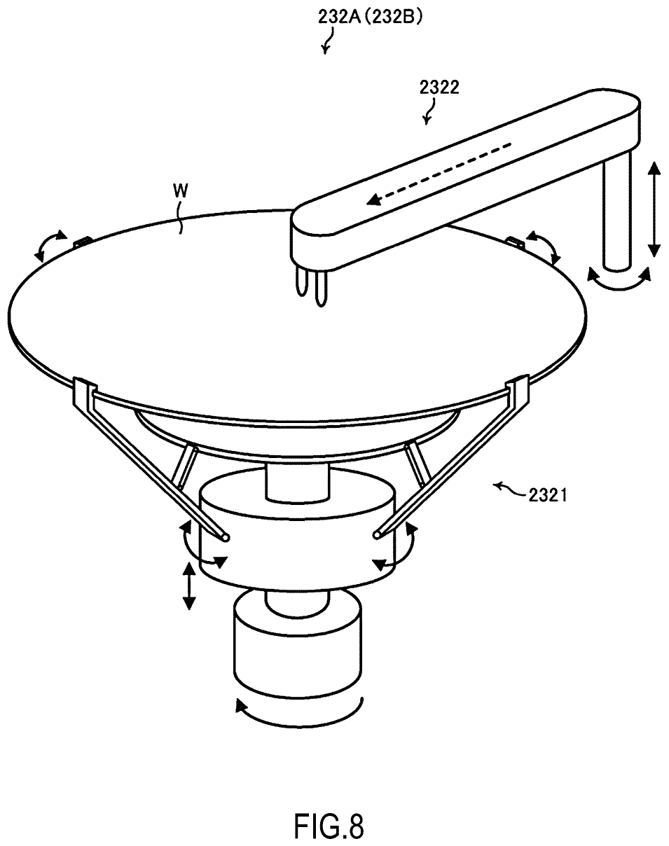

FIG. 8 is a perspective view showing an example of the third finishing units 232A and 232B which perform the drying processing. The third finishing units 232A and 232B include a substrate holding part 2321 that holds the wafer W, and a drying fluid supply part 2322 that supplies a substrate drying fluid to the wafer W. The substrate drying fluid is, for example, IPA vapor and pure water (rinse liquid), and may be a liquid or a two-fluid mixture of a liquid and a gas, or may contain a solid such as dry ice.

In the drying processing performed by the third finishing units 232A and 232B, the wafer W is rotated in a state held at the third finishing position LC3 by the substrate holding part 2321. Then, with the substrate drying fluid supplied to the washed surface of the wafer W from the drying fluid supply part 2322, the drying fluid supply part 2322 is moved to the lateral edge side (radially outer side) of the wafer W. Afterward, the wafer W is dried by being rotated at high speed.

### Substrate Transport Part

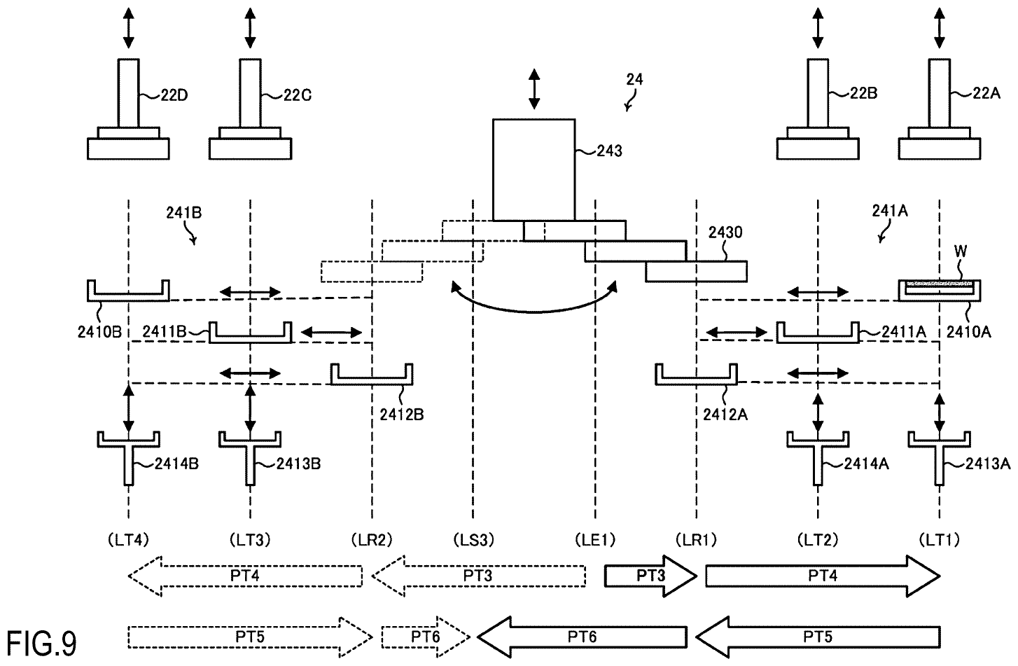

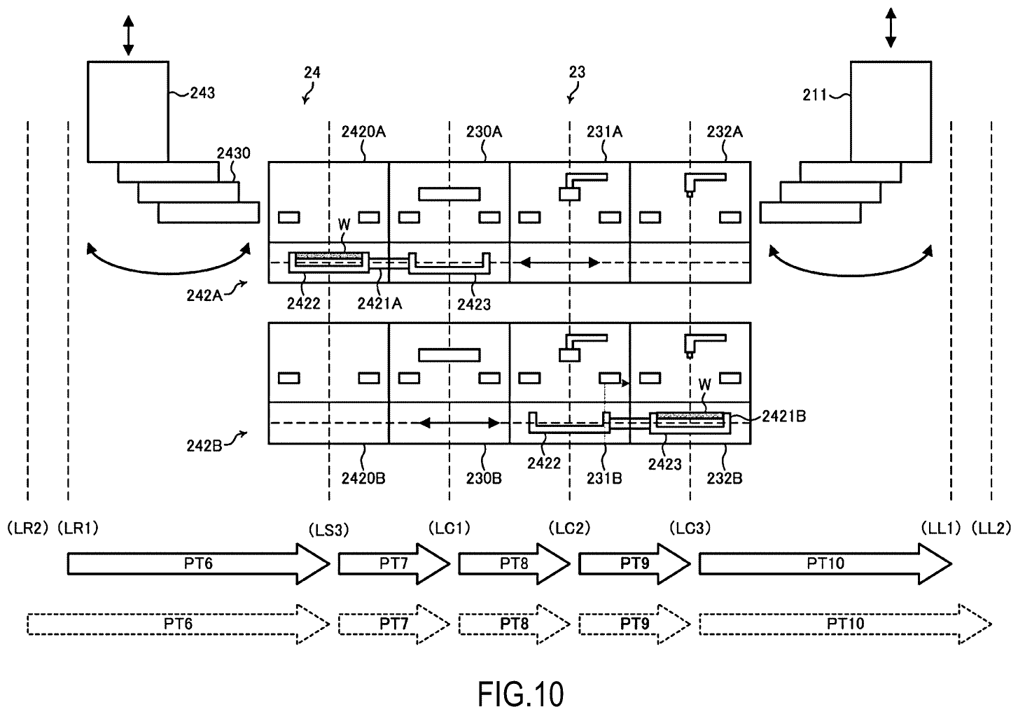

FIG. 9 is a schematic side view showing an example of the substrate transport part 24 (second transport units 241A and 241B and transfer robot 243). FIG. 10 is a schematic side view showing an example of the substrate transport part 24 (third transport units 242A and 242B and transfer robot 243). The substrate transport part 24 is composed of a plurality of transport processing units in which a transport route of the time when transporting the substrate in the transport processing may be selected.

As shown in FIG. 2, the substrate transport part 24 includes a first transport unit 240, second transport units 241A and 241B, third transport units 242A and 242B, and a transfer robot 243. In this embodiment, the second transport unit includes a second transport unit 241A arranged on the first and second polishing unit 22A and 22B side (hereinafter referred to as a “right side”), and a second transport unit 241B arranged on the third and fourth polishing unit 22C and 22D side (hereinafter referred to as a “left side”). Further, the third transport unit includes a third transport unit 242A arranged in the upper stage and a third transport unit 242B arranged in the lower stage.

The first transport unit 240 is arranged between the polishing part 22 and the finishing part 23, and is configured to be movable in the horizontal direction between a first transport start position LS1 and a first transport end position LE1 along the long-side direction of the housing 20.

As the transport processing PT on the wafer W, the first transport unit 240 performs a pre-polishing transport processing PT2 of transporting a wafer W before the polishing processing, which is supplied by the supply discharge robot 211, from the first transport start position LS1 to the first transport end position LE1.

The second transport units 241A and 241B are arranged on the polishing part 22 side and are configured to be movable in the horizontal direction along the long-side direction of the housing 20 and movable in the up-down direction.

The right-side second transport unit 241A includes a plurality (in this embodiment, three arranged in three stages in the up-down direction) of transport mechanisms 2410A to 2412A that move in the horizontal direction independently of each other between a transfer robot handover position LR1 and the polishing unit handover positions LT1 and LT2, a first pusher mechanism 2413A that is arranged at the polishing unit handover position LT1 and moves in the up-down direction, and a second pusher mechanism 2414A that is arranged at the polishing unit handover position LT2 and moves in the up-down direction.

The left-side second transport unit 241B includes a plurality (in this embodiment, three arranged in three stages in the up-down direction) of transport mechanisms 2410B to 2412B that move in the horizontal direction independently of each other between a transfer robot handover position LR2 and the polishing unit handover positions LT3 and LT4, a first pusher mechanism 2413B that is arranged at the polishing unit handover position LT3 and moves in the up-down direction, and a second pusher mechanism 2414B that is arranged at the polishing unit handover position LT4 and moves in the up-down direction.

As the transport processing PT on the wafer W, each of the plurality of transport mechanisms 2410A to 2412A and 2410B to 2412B in the second transport units 241A and 241B performs a pre-polishing transport-in processing PT4 of transporting the wafer W before the polishing processing from the transfer robot handover positions LR1 and LR2 to the polishing unit handover positions LT1 to LT4, and a post-polishing transport-out processing PT5 of transporting the wafer W after the polishing processing from the polishing unit handover positions LT1 to LT4 to the transfer robot handover positions LR1 and LR2.

The third transport units 242A and 242B are arranged on the finishing part 23 side and are configured to be movable in the horizontal direction between a third transport start position LS3, the first finishing position LC1, the second finishing position LC2, and the third finishing position LC3 along the long-side direction of the housing 20.

The upper-stage third transport unit 242A includes a wafer station 2420A that holds the wafer W after the polishing processing and at which the wafer W is capable of standing by during a standby time WS, and a transport mechanism 2421A that moves in the horizontal direction between the wafer station 2420A and the first to third finishing units 230A to 232A. The lower-stage third transport unit 242B includes a wafer station 2420B that holds the wafer W after the polishing processing and at which the wafer W is capable of standing by during the standby time WS, and a transport mechanism 2421B that moves in the horizontal direction between the wafer station 2420B and the first to third finishing units 230B to 232B. The transport mechanisms 2421A and 2421B include a pair of left and right hands 2422 and 2423 for handing over the wafer W. One hand 2422 is used when handing over the wafer W after the polishing processing and before the finishing processing, and the other hand 2423 is used when handing over the wafer W after the finishing processing. For example, the hands 2422 and 2423 are configured to be capable of extending and flipping the wafer W upside down.

As the transport processing PT on the wafer W, the transport mechanisms 2421A and 2421B in the third transport units 242A and 242B perform a post-polishing transport processing PT7 of transporting the wafer W after the polishing processing from the third transport start position LS3 to the finishing part 23 (in this embodiment, the first finishing position LC1 of the first finishing units 230A and 230B), and during-finishing transport processings PT8 and PT9 of transporting the wafer W during the finishing processing between each finishing unit. In this embodiment, as the during-finishing transport processing, the third transport units 242A and 242B perform a first during-finishing transport processing PT8 of transporting the wafer W during the finishing processing from the first finishing units 230A and 230B (first finishing position LC1) to the second finishing units 231A and 231B (second finishing position LC2), and a second during- finishing transport processing PT9 of transporting the wafer W during the finishing processing from the second finishing units 231A and 231B (second finishing position LC2) to the third finishing units 232A and 232B (third finishing position LC3).

The transfer robot 243 is configured to be movable in the up-down direction and movable in the turning direction. The transfer robot 243 includes a hand 2430 for handing over the wafer W. For example, the hand 2430 is configured to be extendable and capable of flipping the wafer W upside down.

As the transport processing PT on the wafer W, the transfer robot 243 performs a pre-polishing transport processing PT3 of receiving the wafer W before the polishing processing from the first transport unit 240 at the first transport end position LE1 and handing over the wafer W to the second transport units 241A and 241B at the transfer robot handover positions LR1 and LR2, and a post-polishing transport processing PT6 of receiving the wafer W after the polishing processing from the second transport units 241A and 241B at the transfer robot handover positions LR1 and LR2 and handing over the wafer W to the third transport units 242A and 242B at the third transport start position LS3.

### Control Unit

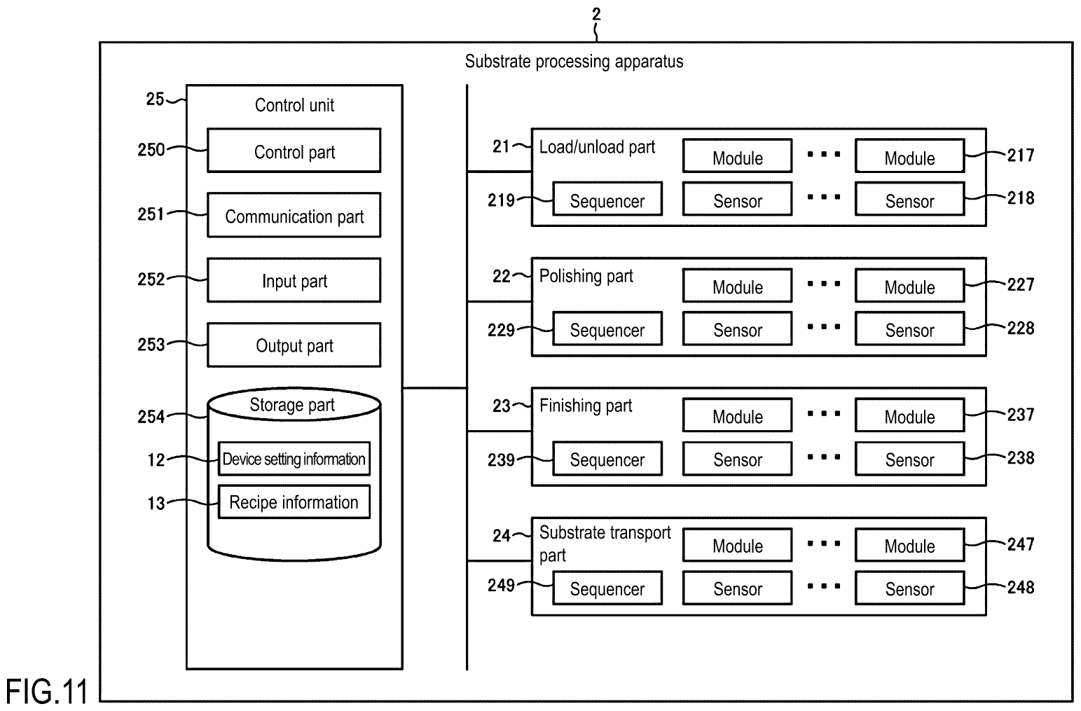

FIG. 11 is a block diagram showing an example of the substrate processing apparatus 2. The control unit 25 is electrically connected to each part 21 to 24 and functions as a control part that comprehensively controls each part 21 to 24. Hereinafter, a control system (modules, sensors, and sequencers) of the polishing part 22, the finishing part 23, and the substrate transport part 24 will be described as an example. Since the basic configuration and function of the load/unload part 21 are also common with the other parts, descriptions thereof will be omitted.

The polishing part 22 includes a plurality of modules 227 that are arranged respectively at each substrate processing unit (in this embodiment, the first to fourth polishing units 22A to 22D) and serve as control targets, a plurality of sensors 228 that are arranged respectively at the plurality of modules 227 and detect data (detection values) necessary for the control on each module 227, and a sequencer 229 that controls the action of each module 227 based on the detection value of each sensor 228.

The finishing part 23 includes a plurality of modules 237 that are arranged respectively at each substrate processing unit (in this embodiment, the first to third finishing units 230A to 232A and 230B to 232B) and serve as control targets, a plurality of sensors 238 that are arranged respectively at the plurality of modules 237 and detect data (detection values) necessary for the control on each module 237, and a sequencer 239 that controls the action of each module 237 based on the detection value of each sensor 238.

The substrate transport part 24 includes a plurality of modules 247 that are arranged respectively at each transport processing unit (in this embodiment, the first transport unit 240, the second transport units 241A and 241B, the third transport units 242A and 242B, and the transfer robot 243) and serve as control targets, a plurality of sensors 248 that are arranged respectively at the plurality of module 247 and detect data (detection values) necessary for the control on each module 247, and a sequencer 249 that controls the action of each module 247 based on the detection value of each sensor 248.

The modules 227, 237, and 247 include a rotating motor, a linear motor, an air actuator, a hydraulic actuator, etc., provided at each part, and perform rotational motion and linear motion. Further, the sensors 228, 238, and 248 include, for example, a linear sensor, an encoder sensor, a limit sensor, a torque sensor, an acceleration sensor, an angular velocity sensor, a current sensor, a flow rate sensor, a pressure sensor, a vibration sensor, a temperature sensor, a proximity sensor, etc.

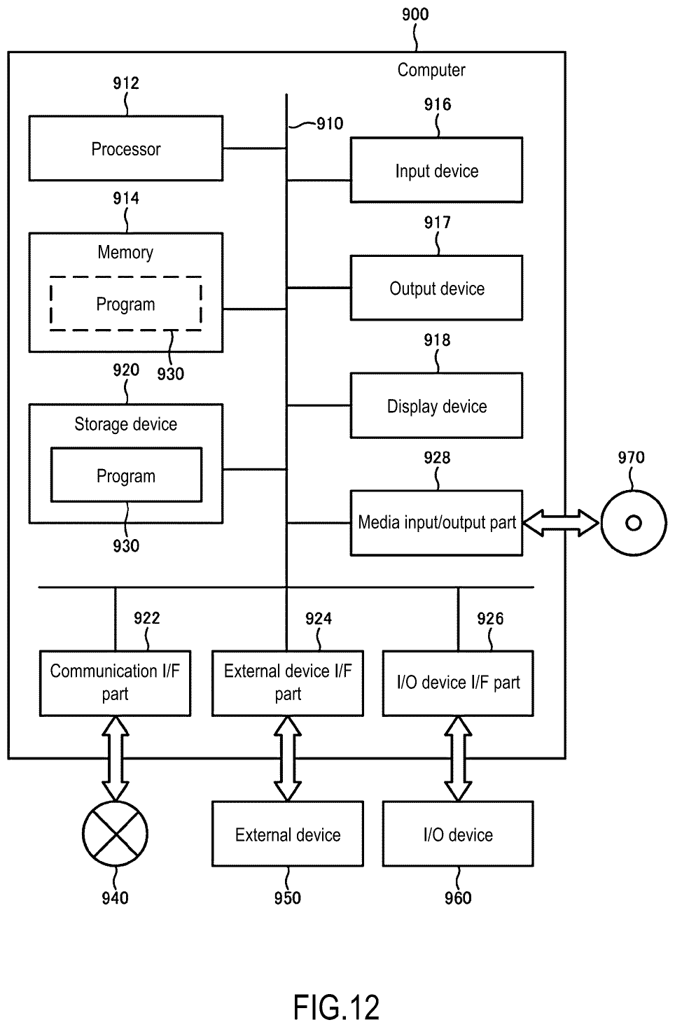

The control unit 25 includes a control part 250, a communication part 251, an input part 252, an output part 253, and a storage part 254. For example, the control unit 25 is composed of a general-purpose or dedicated computer (see FIG. 12 to be described later).

The communication part 251 is connected to the network 4 and functions as a communication interface for sending and receiving various data. The input part 252 receives various input operations. The output part 253 functions as a user interface by outputting various information via a display screen, signal tower lighting, and buzzer sounds.

The storage part 254 stores various programs (operating system (OS), application programs, web browsers, etc.) and data (device setting information 12, recipe information 13, etc.) to be used in the action of the substrate processing apparatus 2. The device setting information 12 and the recipe information 13 are data that are editable by the user via the display screen.

The control part 250 acquires detection values of the plurality of sensors 218, 228, 238, and 248 (hereinafter referred to as a “sensor group”) via the plurality of sequencers 219, 229, 239, and 249 (hereinafter referred to as a “sequencer group”), and causes the plurality of modules 217, 227, 237, and 247 (hereinafter referred to as a “module group”) to act in cooperation. Then, the substrate processing apparatus 2 performs an automatic operation by controlling each part 21 to 24 with the control part 250 and sequentially performing the polishing processing PP, the finishing processing PC, the transport processing PT, etc. on a plurality of wafers W in the wafer cassette.

The device setting information 12 is information that defines the action content of the substrate processing apparatus 2 of the time when a processing action (automatic operation) repeating the substrate processing and the transport processing on the plurality of wafers W is performed in the substrate processing apparatus 2. The device setting information 12 has a plurality of device setting items, and the action content of the substrate processing apparatus 2 is defined by setting a setting value respectively for each of the plurality of device setting items.

The device setting items include, for example, a coordinate value, a moving speed, a moving acceleration, a timer time, etc. of each transport processing unit. The device setting items may also include a coordinate value, a moving speed, a moving acceleration, a timer time, etc. of the substrate processing unit (in this embodiment, the polishing units 22A to 22D and the finishing units 230A to 232A and 230B to 232B).

The recipe information 13 is information indicating processing contents of the polishing processing PP and the finishing processing PC. The recipe information 13 has a plurality of recipe setting items, and the processing contents of the polishing processing PP and the finishing processing PC are defined by setting a setting value respectively for each of the plurality of recipe setting items. The recipe information 13 may be set for each one wafer W or may be set for each plurality of wafers W constituting a lot.

The recipe setting items of the polishing processing PP include, for example, a table rotation speed of the polishing table 220, a top ring pressing time of the top ring 221, a wafer pressing load, a wafer rotation speed, a supply amount of the polishing fluid supplied by the polishing fluid supply part 222, a supply timing, a dresser action time of the dresser 223, an atomizer action time of the atomizer 224, etc.

The recipe setting items of the finishing processing PC include, for example, a roll sponge action time, a roll sponge rotation speed, a wafer rotation speed, a supply amount and a supply timing of the substrate washing fluid in the roll sponge washing processing (first finishing processing PC1), a pen sponge action time, a pen sponge rotation speed, a wafer rotation speed, a supply amount and a supply timing of the substrate washing fluid in the pen sponge washing processing (second finishing processing PC2), a drying action time, a wafer rotation speed, a supply amount and a supply timing of the substrate drying fluid in the drying processing (third finishing processing PC3), etc.

### Hardware Configuration of Each Device

FIG. 12 is a hardware configuration view showing an example of a computer 900. The control unit 25 of the substrate processing apparatus 2 and the information processing device 3A are each composed of a general-purpose or dedicated computer 900.

As shown in FIG. 12, the computer 900 includes, as main components, a bus 910, a processor 912, a memory 914, an input device 916, an output device 917, a display device 918, a storage device 920, a communication interface (I/F) part 922, an external device I/F part 924, an input/output (I/O) device I/F part 926, and a media input/output part 928. These components may be omitted as appropriate depending on the use of the computer 900.

The processor 912 is composed of one or more arithmetic processing devices (central processing unit (CPU), micro-processing unit (MPU), digital signal processor (DSP), graphics processing unit (GPU), etc.), and acts as a control part that coordinates the entire computer 900. The memory 914 stores various data and a program 930 and is composed of, for example, a volatile memory (DRAM, SRAM, etc.) that functions as a main memory, a non-volatile memory (ROM), a flash memory, etc.

The input device 916 is composed of, for example, a keyboard, a mouse, a numeric keypad, an electronic pen, etc. and functions as an input part. The output device 917 is composed of, for example, a sound (voice) output device, a vibration device, etc. and functions as an output part. The display device 918 is composed of, for example, a liquid crystal display, an organic EL display, an electronic paper, a projector, etc. and functions as an output part. The input device 916 and the display device 918 may be integrally configured, such as a touch panel display. The storage device 920 is composed of, for example, an HDD, a solid state drive (SSD), etc. and functions as a storage part. The storage device 920 stores various data necessary for executing the operating system and the program 930.

The communication I/F part 922 is connected in a wired or wireless manner to a network 940 (which may be the same as the network 4 in FIG. 1) such as the Internet or an intranet, and functions as a communication part that sends and receives data to and from other computers according to a predetermined communication standard. The external device I/F part 924 is connected in a wired or wireless manner to an external device 950 such as a camera, a printer, a scanner, a reader/writer, and functions as a communication part that sends and receives data to and from the external device 950 according to a predetermined communication standard. The I/O device I/F part 926 is connected to an I/O device 960 such as various sensors and actuators, and functions as a communication part that sends and receives various signals and data, such as detection signal detected by sensors and control signals for actuators, to and from the I/O device 960. The media input/output part 928 is composed of, for example, a drive device such as a DVD drive and a CD drive and performs read and write of data from and to media (non-transitory storage media) 970 such as a DVD and a CD.

In the computer 900 having the above configuration, the processor 912 calls the program 930 stored in the storage device 920 to the memory 914 to execute the program 930, and controls each part of the computer 900 via the bus 910. The program 930 may be stored in the memory 914 instead of the storage device 920. The program 930 may be recorded on the media 970 in an installable file format or an executable file format and may be provided to the computer 900 via the media input/output part 928. The program 930 may also be provided to the computer 900 by downloading over the network 940 via the communication I/F part 922. Further, in the computer 900, the various functions realized by the processor 912 executing the program 930 may also be realized by hardware such as FPGA and ASIC, for example.

The computer 900 is composed of, for example, a stationary computer or a portable computer and is an electronic device of any form. The computer 900 may be a client-type computer, may be a server-type computer or a cloud-type computer, or may be, for example, an embedded-type computer called a control panel, a controller (including a microcontroller, a programmable logic controller, and a sequencer), etc. The computer 900 may also be applied to devices other than the substrate processing apparatus 2 and the information processing device 3A.

### Information Processing Device

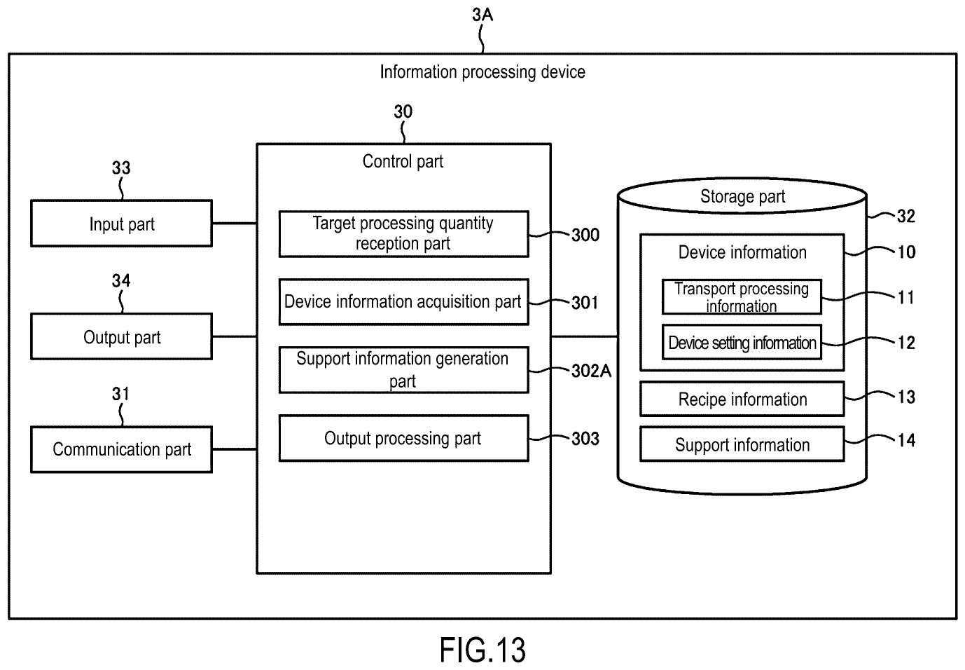

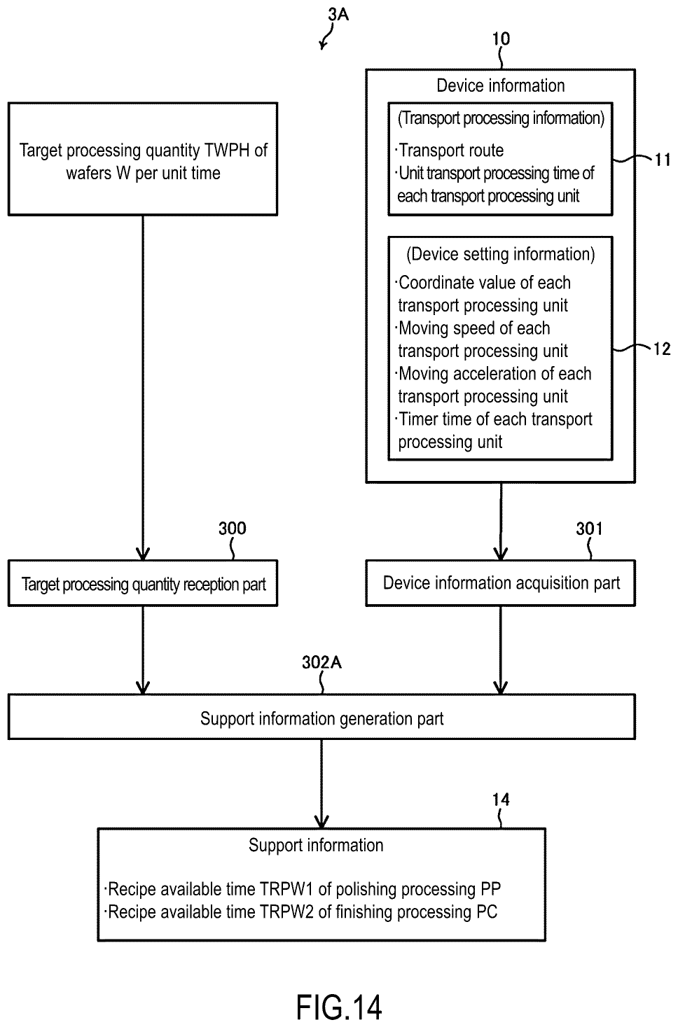

FIG. 13 is a block diagram showing an example of the information processing device 3A according to the first embodiment. FIG. 14 is a function illustrative view showing an example of the information processing device 3A according to the first embodiment.

The information processing device 3A includes a control part 30, a communication part 31, a storage part 32, an input part 33, and an output part 34. The specific hardware configuration of each part 30 to 34 shown in FIG. 13 is formed by the general-purpose or dedicated computer 900 shown in FIG. 12, so detailed descriptions thereof will be omitted.

The control part 30 functions as a target processing quantity reception part 300, a device information acquisition part 301, a support information generation part 302A, and an output processing part 303. The communication part 31 is connected to an external device (e.g., the substrate processing apparatus 2) via the network 4 and functions as a communication interface for sending and receiving various data. The storage part 32 stores various programs (operating system, information processing program, etc.), data (the device information 10, the transport processing information 11, the device setting information 12, the recipe information 13, and the support information 14) etc., to be used in the action of the information processing device 3A. The input part 33 receives various input operations. The output part 34 functions as a user interface by outputting various information via a display screen or voice.

The target processing quantity reception part 300 receives a target processing quantity TWPH of wafers W per unit time of the time when a processing action (automatic operation) repeating the substrate processing and the transport processing on a plurality of wafers W is performed in the substrate processing apparatus 2. For example, the target processing quantity reception part 300 displays a display screen on the output part 34 and receives a target processing quantity TWPH as an input operation of the user on the display screen.

The device information acquisition part 301 acquires device information 10 including various information of the time when the substrate processing apparatus 2 performs the processing action. The device information 10 includes transport processing information 11 and device setting information 12. The device information 10 may at least include the transport processing information 11, and may further include other information. The device setting information 12 is the same as the information stored in the storage part 254 of the substrate processing apparatus 2, so detailed descriptions thereof will be omitted herein.

The transport processing information 11 is information that defines the action state of the transport processing of the time when the substrate processing apparatus 2 performs the processing action. In this embodiment, transport processings PT1 to PT10 are performed by the supply discharge robot 211, the first transport unit 240, the second transport units 241A and 241B, the third transport units 242A and 242B, and the transfer robot 243 as the plurality of transport processing units.

The transport processing information 11 includes, for example, a transport route selected when executing the processing action, and unit transport processing times TT1 to TT10 required for each of the transport processings PT1 to PT10 performed by the plurality of transport processing units when executing the processing action. The transport processing information 11 may be acquired for each one wafer W or may be acquired for each plurality of wafers W constituting a lot.

A path or a sequence by which a wafer W passes each transport processing unit when the wafer W is transported by the plurality of transport processing units is acquired as the transport route. The transport route differs depending on the processing content for the wafer W, such as the difference between the case where the washing processing is performed after the polishing processing and the case where the washing processing is performed both before the polishing processing and after the polishing processing. Further, the transport route differs depending on the difference in the priorities among transport processings in the case where a plurality of transport processings are performed in one transport processing unit. For example, in the transfer robot 243, in the case where the pre-polishing transfer processing PT3 and the post-polishing transfer processing PT6 may be performed at the same time, the transport route differs depending on which one is to be performed as the higher priority transport processing.

For example, a substrate supply time TT1, a pre-polishing transport time TT2, a pre-polishing transfer time TT3, a pre-polishing transport-in time TT4, a post-polishing transport-out time TT5, a post-polishing transfer time TT6, a post-polishing transport time TT7, a first during-finishing transport time TT8, a second during-finishing transport time TT9, and a substrate discharge time TT10 are acquired as the unit transport processing times TT1 to TT10.

For example, in the case where the transport processing information 11 and the device setting information 12 are stored in an external production management device as generation history information of the time when the substrate processing apparatus 2 performed the processing action in the past, the device information acquisition part 301 acquires the device information 10 from the external production management device. The device information acquisition part 301 may acquire the device information 10, for example, by sending and receiving data to and from the substrate processing apparatus 2 via the communication part 31 or by referring to the storage part 32.

In particular, the unit transport processing times TT1 to TT10 may be actual measured values obtained by measuring the time when the transport processing unit actually acts. Further, the unit transport processing times TT1 to TT10 may also be theoretical values calculated from the specifications of the transport processing unit, and in the case where the moving speed, the moving acceleration, etc. of the transport processing unit are included in the device setting information 12, the unit transport processing times TT1 to TT10 may also be calculated based on the setting values thereof. Furthermore, the unit transport processing times TT1 to TT10 may also be inferred values that take into account errors (actual action errors) between the above theoretical values and the actual measured values when the transport processing unit actually acts, or the actual action errors may be calculated using an estimation model such as machine learning to calculate the unit transport processing times TT1 to TT10 based on the actual measured values and the actual action errors.

Based on the target processing quantity TWPH per unit time received by the target processing quantity reception part 300 and the device information 10 acquired by the device information acquisition part 301, the support information generation part 302A generates support information 14 including a recipe available time TRPW that is available for the substrate processing performed according to the recipe information 13.

In this embodiment, since the substrate processing apparatus 2 performs the polishing processing PP and the finishing processing PC as the substrate processing, a recipe available time TRPW1 for the polishing processing PP and a recipe available time TRPW2 for the finishing processing PC are calculated as the recipe available time TRPW. Hereinafter, a calculation method for the support information generation part 302A to respectively calculate the recipe available times TRPW1 and TRPW2 of the polishing processing PP and the finishing processing PC will be described.

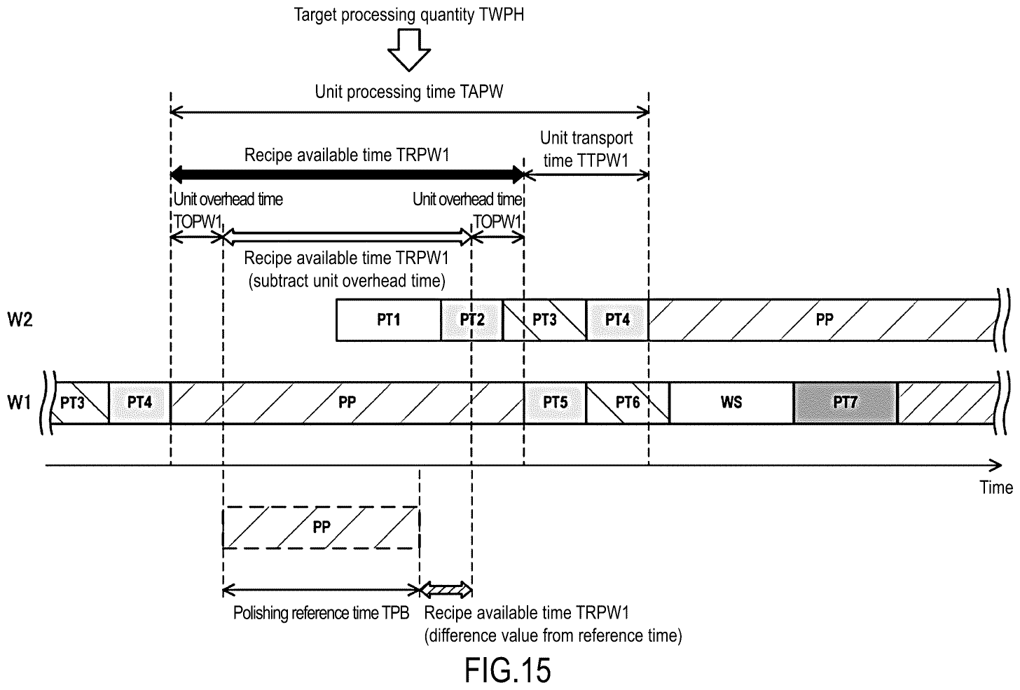

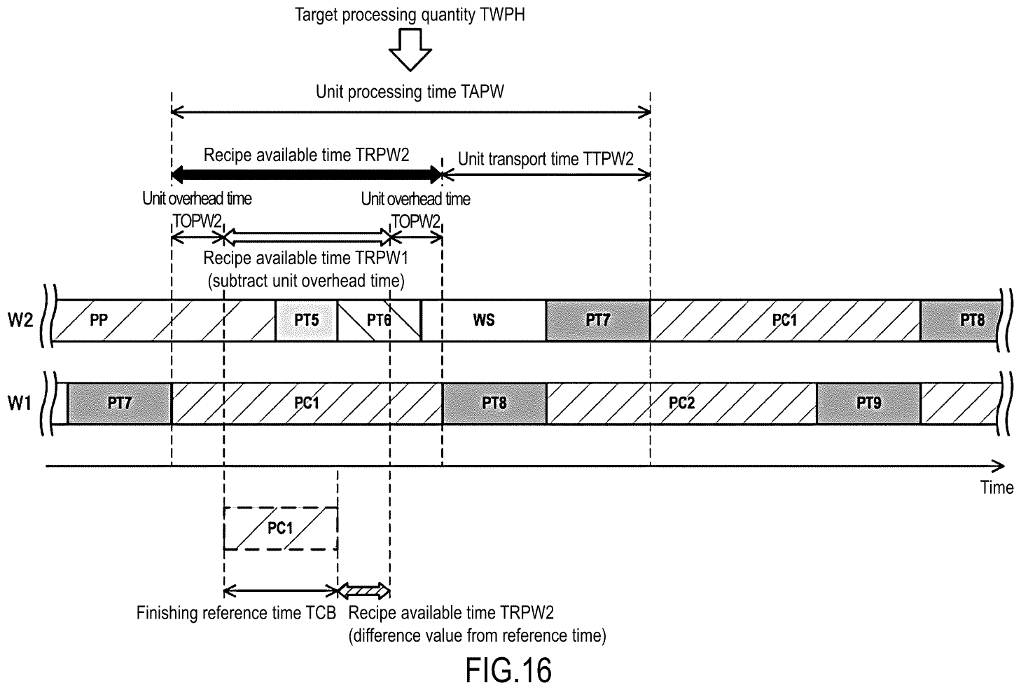

FIG. 15 is a view showing a calculation example of the recipe available time TRPW1 for the polishing processing PP. FIG. 16 is a view showing a calculation example of the recipe available time TRPW2 for the finishing processing PC. The transport routes in FIG. 15 and FIG. 16 are the same as those in FIG. 3 and FIG. 4, and illustrate the case where the pre-polishing transfer processing PT3 is prioritized over the post-polishing transfer processing PT6. In FIG. 15 and FIG. 16, to facilitate description, the polishing processing time (corresponding to a polishing processing time TP shown in FIG. 3) required for the polishing processing PP and the finishing processing time (corresponding to finishing processing times TC1, TC2, and TC3 shown in FIG. 4) required for the first to third finishing processings PC1, PC2, and PC3 are shown, but calculation of these times as the recipe available times TRPW1 and TRPW2 is realized as a function of the support information generation part 302A.

First, the support information generation part 302A converts the target processing quantity TWPH per unit time into a unit processing time TAPW per wafer W (e.g., a wafer W1 and a wafer W2). For example, in the case where the target processing quantity TWPH is “60 sheets/hour”, the unit processing time TAPW is converted as “60 seconds/sheet”.

Next, the support information generation part 302A calculates a unit transport time TTPW required for the transport processing PT per wafer W based on the transport processing information 11. At that time, the unit transport time TTPW is calculated by adding up the unit transport processing times TT1 to TT10 according to the transport route.

For example, in the case where the transport processing PT performed after the end of the polishing processing PP until the start of the polishing processing PP on a next wafer W2 is specified as a part of the pre-polishing transfer processing PT3 and the pre-polishing transport-in processing PT4 as shown in FIG. 15, as the unit transport processing times TT required, a unit transport time TTPW1 is calculated by adding up a part of the pre-polishing transfer time TT3 and the pre-polishing transport-in time TT4. When specifying the transport processing PT described above, it may also be specified as the post-polishing transport-out processing PT5 and a part of the post-polishing transfer processing PT6, and in that case, the unit transport time TTPW1 may be calculated by adding up the post-polishing transport-out time TT5 and a part of the post-polishing transfer time TT6.

Further, in the case where the transport processing PT performed after the end of the first finishing processing PCI until the start of the first finishing processing PCI on a next wafer W2 is specified as the post-polishing transfer processing PT7 and the first during-finishing transfer processing PT8 as shown in FIG. 16, as the unit transport processing time TT required, a unit transport time TTPW2 is calculated by adding up the post-polishing transfer time TT7 and the first during-finishing transport time TT8.

That is, the support information generation part 302A specifies the transport processing PT performed after the end of the substrate processing until the start of the substrate processing on a next wafer W2 according to the transport route (path or sequence by which the wafer W passes each transport processing unit), and calculates the unit transport time TTPW by adding up the unit transport processing times required for the specified transport processing PT.

Then, the support information generation part 302A calculates the recipe available time TRPW per wafer W by subtracting the unit transport time TTPW from the unit processing time TAPW. In the example of FIG. 15, the recipe available time TRPW1 (black arrow) of the polishing processing PP is calculated by subtracting the unit transport time TTPW1 from the unit processing time TAPW. In the example of FIG. 16, the recipe available time TRPW2 (black arrow) of the finishing processing PC is calculated by subtracting the unit transport time TTPW2 from the unit processing time TAPW.

In addition, based on the device setting information 12, the support information generation part 302A may calculate a unit overhead time TOPW required for a preparation action per wafer W of the time when the preparation action is performed before and after the substrate processing on the wafer W held in the substrate processing unit (in this embodiment, the polishing units 22A to 22D and the finishing units 230A to 232A and 230B to 232B).

The preparation action of the polishing processing PP includes, for example, an adsorption action in which the top ring 221 adsorbs the wafer W before the polishing processing, a turning action of moving to the polishing positions LP1 to LP4, a lowering action of lowering to cause contact with the polishing pad 2200, a rising action of rising such that the top ring 221 separates the wafer W after the polishing processing from the polishing pad 2200, a turning action of moving to the polishing unit handover positions LT1 to LT4, an adsorption release action of releasing the adsorption, etc. The unit overhead time TOPW1 of the polishing processing PP is calculated, as shown in FIG. 15, based on setting values set for the device setting items such as the moving speed, the moving acceleration, the timer time, etc., of the top ring 221 in the device setting information 12.

The preparation action of the finishing processing PC includes, for example, a holding action in which the substrate holding parts 2301, 2311, and 2321 hold the wafer W before the finishing processing, a moving action in which the substrate washing parts 2303 and 2313 move to cause the roll sponge 2300 and the pen sponge 2310 to contact the wafer W before the finishing processing, a moving action of moving to separate the roll sponge 2300 and the pen sponge 2310 from the wafer W after the finishing processing, a holding release action in which the substrate holding parts 2301, 2311, and 2321 release the holding of the wafer W after the finishing processing, etc. The unit overhead time TOPW2 of the finishing processing PC is calculated, as shown in FIG. 16, based on the setting values set for the device setting items such as the timer time of the substrate holding part 2301 and the moving speed and the moving acceleration of the substrate washing part 2303 in the device setting information 12.

Then, the support information generation part 302A may calculate the recipe available time TRPW per wafer W by subtracting the unit transport time TTPW and the unit overhead time TOPW from the unit processing time TAPW. In the example of FIG. 15, the recipe available time TRPW1 (white arrow) of the polishing processing PP is calculated by subtracting the unit transport time TTPW1 and the unit overhead time TOPW1 from the unit processing time TAPW. In the example of FIG. 16, the recipe available time TRPW2 (white arrow) of the finishing processing PC is calculated by subtracting the unit transport time TTPW2 and the unit overhead time TOPW2 from the unit processing time TAPW.

Further, the recipe available time TRPW may also be calculated as a difference value with respect to a predetermined reference time. For example, in the case where the recipe information 13 (which may also be a default value) has already been set, the substrate processing time of the time when the substrate processing is performed according to this recipe information 13 may be calculated, and taking this substrate processing time as a reference time, the recipe available time TRPW may be calculated as a difference value from this reference time. In this embodiment, as the reference time, as shown in FIG. 15, a polishing reference time TPB is calculated, and as shown in FIG. 16, a finishing reference time TCB is calculated, based on the recipe information 13.

Then, the recipe available time TRPW1 (arrow with hatching) for the polishing processing PP is calculated as a difference value with respect to the polishing reference time TPB as shown in FIG. 15. Further, the recipe available time TRPW2 (arrow with hatching) for the finishing processing PC is calculated as a difference value with respect to the finishing reference time TCB as shown in FIG. 16.

At that time, the support information generation part 302A acquires the recipe information 13, for example, by sending and receiving data to and from the substrate processing apparatus 2 via the communication part 31 or by referring to the storage part 32. The recipe information 13 may be based on the user's input operation or may be acquired from an external production management device (not shown). Then, the support information generation part 302A acquires the polishing reference time TPB and the finishing reference time TCB by respectively adding up the times required for the polishing processing PP and the finishing processing PC based on the setting value set for each recipe setting item in the recipe information 13. For example, the support information generation part 302A acquires the polishing reference time TPB based on the setting value set for the recipe setting item of the polishing processing PP. Further, the support information generation part 302A acquires the finishing reference time TCB based on the setting value set for the recipe setting item of the finishing processing PC.

The polishing reference time TPB and the finishing reference time TCB may, for example, take into account actual measured values obtained by measuring the time when the polishing units 22A to 22D and the finishing units 230A to 232A and 230B to 232B actually act. At that time, for example, in the case where the actual measured values are stored in the substrate processing apparatus 2 or an external production management device, the support information generation part 302A may acquire the actual measured values as the polishing reference time TPB and the finishing reference time TCB from the substrate processing apparatus 2 or the external production management device, and may correct, based on the actual measured values, the polishing reference time TPB and the finishing reference time TCB calculated from the recipe information 13.

The output processing part 303 performs an output processing for outputting the support information 14 generated by the support information generation part 302A. For example, the output processing part 303 may display and output the support information 14 via the output part 34 or may store the support information 14 to the storage part 32. Further, the output processing part 303 may send the support information 14 to the substrate processing apparatus 2 via the communication part 31, and the substrate processing apparatus 2 may display and output the support information 14.

### Information Processing Method

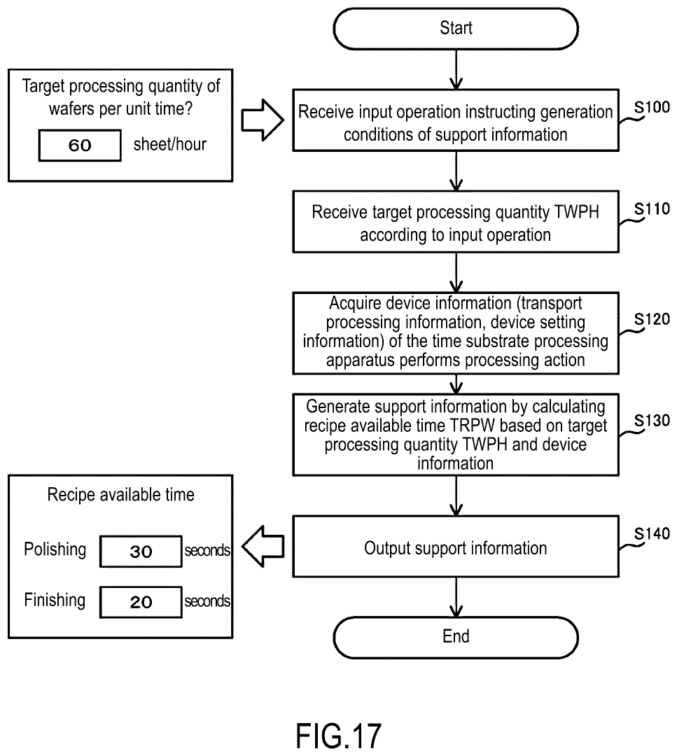

FIG. 17 is a flowchart showing an example of an information processing method performed by the information processing device 3A according to the first embodiment.

First, in step S100, for example, as a user instructs generation conditions (e.g., a lot number of the wafer W serving as the support target, a model number of the substrate processing apparatus 2 serving as the support target, a target processing quantity TWPH of wafers W per unit time, etc.) of the support information 14 on a support screen displayed on the information processing device 3A and instructs start of generation of the support information 14, the information processing device 3A receives the input operation.

Next, in step S110, the target processing quantity reception part 300 receives the target processing quantity TWPH according to the input operation received in step S100.

Next, in step S120, the device information acquisition part 301 acquires device information 10 of the time when the substrate processing apparatus 2 performs a processing action according to the input operation received in step S100. The device information 10 includes transport processing information 11 and device setting information 12. For example, the device information acquisition part 301 acquires the transport processing information 11 associated with the lot number of the wafer W instructed by the input operation and acquires the device setting information 12 associated with the model number of the substrate processing apparatus 2 instructed by the input operation.

Next, in step S130, the support information generation part 302A generates support information 14 by calculating a recipe available time TRPW based on the target processing quantity TWPH received in step S110 and the device information 10 acquired in step S120.

Then, in step S140, the output processing part 303 performs an output processing for outputting the support information 14 generated in step S130, and ends the series of information processing method shown in FIG. 17. In this information processing method, step S110 corresponds to a target processing quantity reception process, step S120 corresponds to a device information acquisition process, step S130 corresponds to a support information generation process, and step S140 corresponds to an output processing process.

As described above, according to the information processing device 3A and the information processing method according to this embodiment, based on the target processing quantity TWPH of wafers W per unit time and the device information 10 including the transport processing information 11 defining the action state of the transport processing, the support information generation part 302A generates the support information 14 including the recipe available time TRPW that is available for the substrate processing performed according to the recipe information 13. Thus, when setting the recipe information 13, since the recipe available time TRPW that is available for the substrate processing can be identified in advance, the setting of the recipe information 13 can be appropriately supported.

That is, instead of the case of setting the recipe information 13 and then calculating the processing quantity of wafers W per unit time of the time when the processing action (automatic operation) is performed according to the set recipe information 13, herein, when the target processing quantity TWPH is set, to achieve the set target processing quantity TWPH, an allowable range of the substrate processing time required for the substrate processing is calculated backward as the recipe available time TRPW. Thus, the user can set the recipe information 13 on the basis of identifying how much time can be used in the substrate processing to achieve the target processing quantity TWPH.

### Second Embodiment

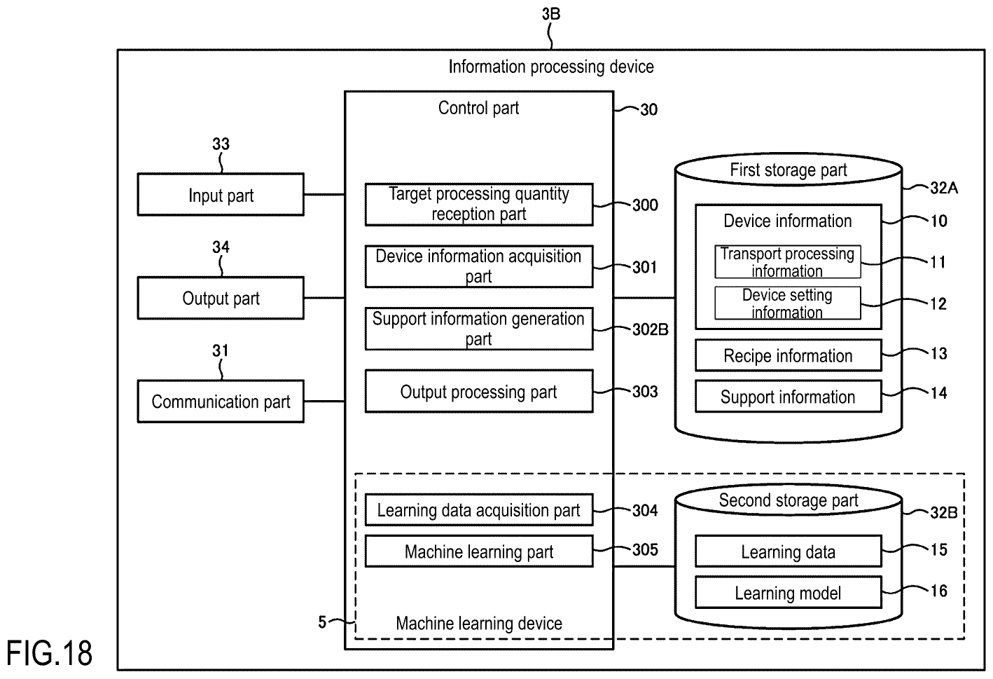

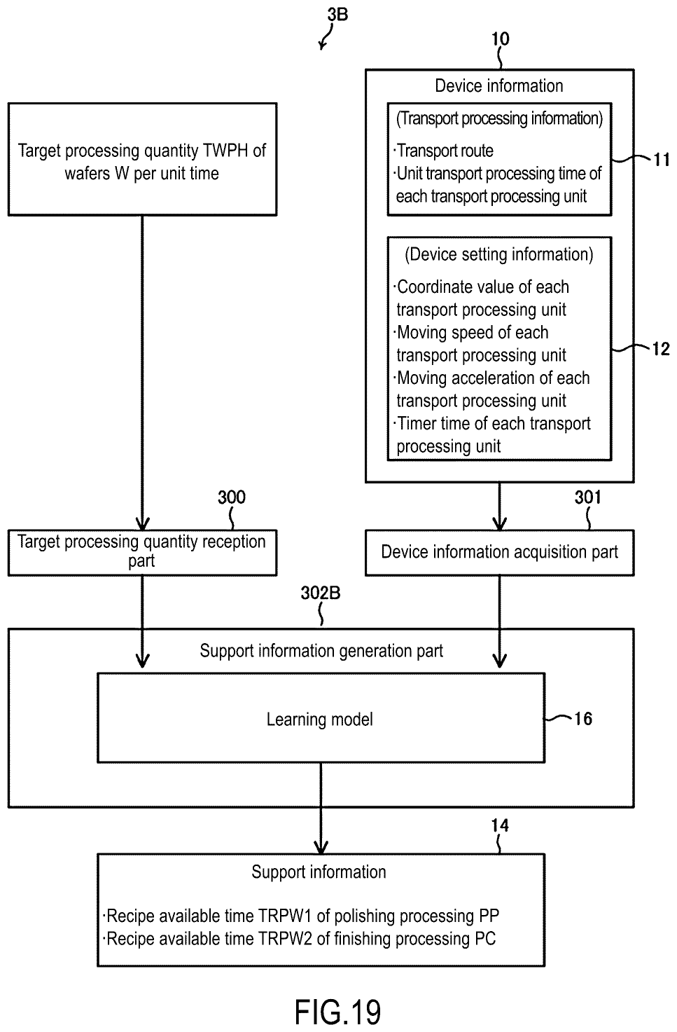

FIG. 18 is a block diagram showing an example of an information processing device 3B according to a second embodiment. FIG. 19 is a function illustrative view showing an example of the information processing device 3B according to the second embodiment.

The information processing device 3B according to the second embodiment differs from the information processing device 3A according to the first embodiment in that the information processing device 3B acts as a machine learning device 5 that generates a learning model 16 by machine learning using learning data 15, and a support information generation part 302B generates the support information 14 using the learning model 16 generated by the machine learning device 5, as shown in FIG. 19. The other configurations and actions of the substrate processing apparatus 2 and the information processing device 3B are similar to those in the first embodiment, so the same reference signs will be labeled and detailed descriptions thereof will be omitted.

The control part 30 further functions as a learning data acquisition part 304 and a machine learning part 305. In this embodiment, although the machine learning device 5 is described as being incorporated into the information processing device 3B, the machine learning device 5 and the information processing device 3B may also be configured as separate devices, and in that case, a learned learning model 16 may be provided to the information processing device 3B via the network 4 or any storage media.

Similar to the storage part 32 in the first embodiment, a first storage part 32A stores various programs and data, and a second storage part 32B stores the learning data 15 and the learning model 16. The second storage part 32B functions as a learning data storage part that stores the learning data 15, and a learned model storage part that stores the learned learning model 16. The first and second storage parts 32A and 32B may be composed of one storage part or may be external storage devices.

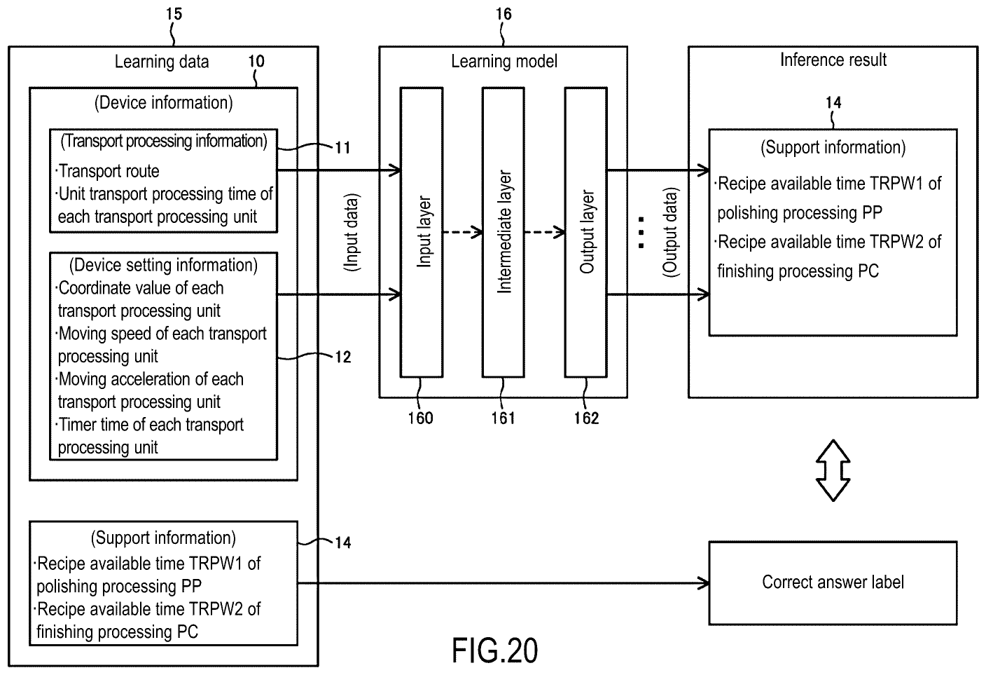

FIG. 20 is a view showing an example of the learning data 15 and the learning model 16. The learning data 15 to be used for machine learning of the learning model 16 are composed of the target processing quantity TWPH of wafers W per unit time and the device information 10 as input data, and the support information 14 including the recipe available time TRPW as output data. The device information 10 may at least include the transport processing information 11, and may further include other information (e.g., device setting information 12).

For example, in the case where generation history information of the time when the substrate processing apparatus 2 performed the processing action in the past is stored in a database of an external production management device, the learning data acquisition part 304 acquires the processing quantity of wafers W per unit time and the device information 10 from the external production management device, and calculates the recipe available time TRPW of that time based on the generation history information. Then, the learning data acquisition part 304 acquires a plurality of sets of learning data 15 associating them, and stores the plurality of sets of learning data 15 to the second storage part 32B.

The learning model 16, for example, adopts the structure of a neural network and includes an input layer 160, an intermediate layer 161, and an output layer 162. Synapses (not shown) that respectively connect each neuron are stretched between each layer, and a weight is respectively associated with each synapse. A weight parameter group composed of the weight of each synapse is adjusted by machine learning. The input layer 160 has neurons in a quantity corresponding to the target processing quantity TWPH and the device information 10 serving as the input data, and each value of the target processing quantity TWPH and the device information 10 is inputted to each neuron, respectively. The output layer 162 has neurons in a quantity corresponding to the support information 14 serving as the output data, and a prediction result (inference result) of the support information 14 for the target processing quantity TWPH and the device information 10 is outputted as the output data.

The machine learning part 305 executes machine learning using a plurality of sets of learning data 15 stored in the second storage part 32B. That is, the machine learning part 305 inputs a plurality of sets of learning data 15 to the learning model 16, generates a learned learning model 16 by causing the learning model 16 to learn the correlation between the input data and the output data included in the learning data 15, and stores that learning model 16 (specifically, adjusted weight parameter group) to the second storage part 32B.

The support information generation part 302B generates support information 14 for the device information 10 and the transport processing information 11 by inputting, to the learning model 16, a target processing quantity TWPH received by the target processing quantity reception part 300 and device information 10 acquired by the device information acquisition part 301.

### Machine Learning Method

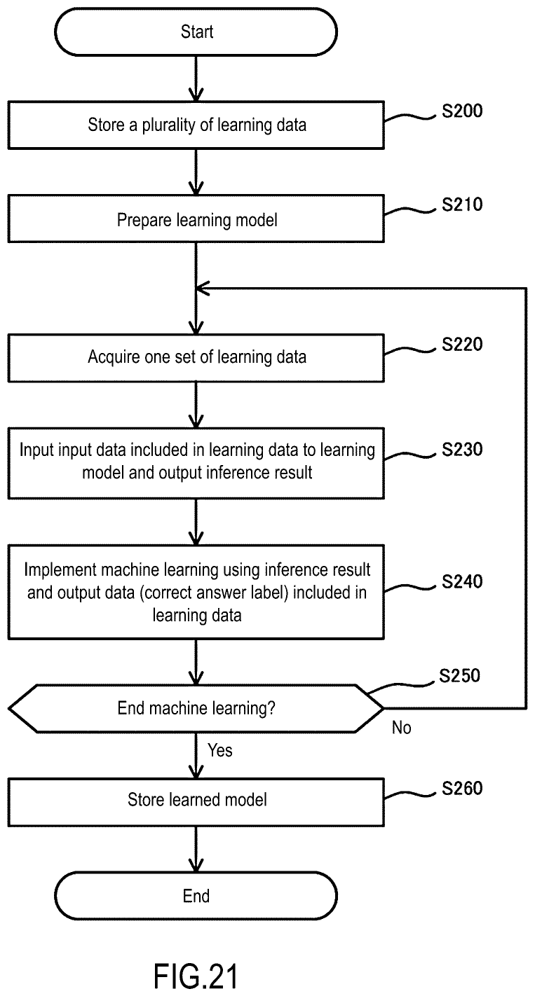

FIG. 21 is a flowchart showing an example of a machine learning method performed by the machine learning device 5.

First, in step S200, as an advance preparation for starting machine learning, the learning data acquisition part 304 acquires learning data 15 in a desired quantity and stores the acquired learning data 15 to the second storage part 32B.

Next, in step S210, to start machine learning, the machine learning part 305 prepares a pre-learning learning model 16 in which the weight of each synapse is set to an initial value.

Next, in step S220, the machine learning part 305 acquires, for example, one set of learning data 15 randomly from a plurality of sets of learning data 15 stored in the second storage part 32B.

Next, in step S230, the machine learning part 305 inputs fluid supply information (input data) included in the one set of learning data 15 to the input layer 160 of the pre-learning (or during-learning) learning model 16 that has been prepared. As a result, an output data is outputted as an inference result from the output layer 162 of the learning model 16, but this output data has been generated by the pre-learning (or during-learning) learning model 16. Thus, in the pre-learning (or during-learning) state, the output data outputted as the inference result shows information different from the output data (correct answer label) included in the learning data 15.

Next, in step S240, the machine learning part 305 executes machine learning by comparing the output data (correct answer label) included in the one set of learning data 15 acquired in step S220 with the output data (inference result) outputted as the inference result from the output layer 162 in step S230, and executing a processing (backpropagation) of adjusting the weight of each synapse.

Next, in step S250, the machine learning part 305 determines whether a predetermined learning end condition has been satisfied, for example, based on an evaluation value of an error function based on the output data (correct answer label) included in the learning data 15 and the output data serving as the inference result, or based on a remaining number of the unlearned learning data 15 stored in the second storage part 32B.

In step S250, in the case where the machine learning part 305 determines that the learning end condition has not been satisfied and machine learning is to be continued (“No” in step S250), returning to step S220, the processes of steps S220 to S240 are executed multiple times on the during-learning learning model 16 using the unlearned learning data 15. On the other hand, in step S250, in the case where the machine learning part 305 determines that the learning end condition has been satisfied and machine learning is to be ended (“Yes” in step S250), the process proceeds to step S260.

Then, in step S260, the machine learning part 305 stores, to the second storage part 32B, the learned learning model 16 (adjusted weight parameter group) generated by adjusting the weight associated with each synapse, and ends the series of machine learning method shown in FIG. 21. In the above machine learning method, step S200 corresponds to a learning data storage process, steps S210 to S250 correspond to a machine learning process, and step S260 corresponds to a learned model storage process.

As described above, according to the machine learning device 5 and the machine learning method according to this embodiment, it is possible to provide a learning model 16 capable of generating (inferring) the support information 14 including the recipe available time TRPW from the target processing quantity TWPH and the device information 10.

### Information Processing Method

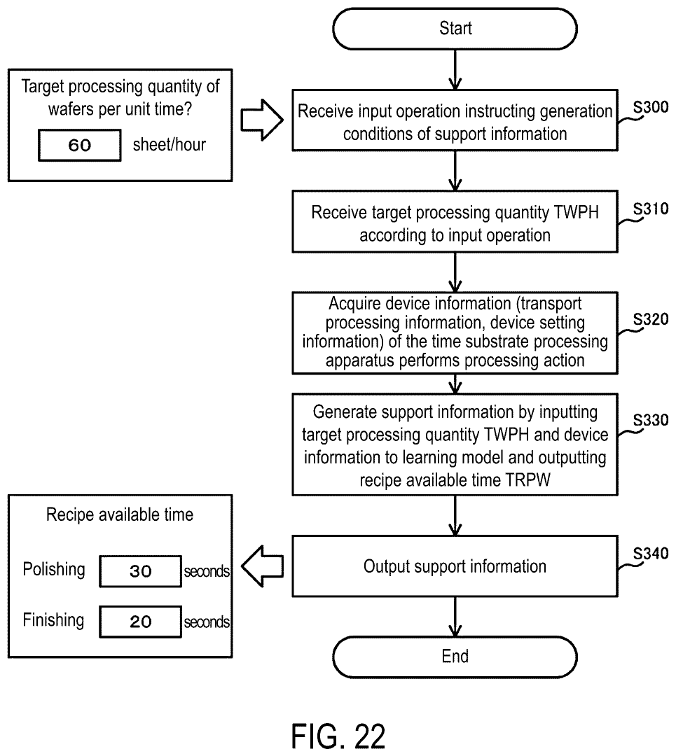

FIG. 22 is a flowchart showing an example of an information processing method performed by the information processing device 3B according to the second embodiment.

First, in step S300, similar to the first embodiment, as the user instructs generation conditions of the support information 14 and start of generation of the support information 14, in step S310, the target processing quantity reception part 300 receives a target processing quantity TWPH. Then, in step S320, the device information acquisition part 301 acquires device information 10.

Next, in step S330, the support information generation part 302B generates the support information 14 for the target processing quantity TWPH and the device information 10 based on output data outputted from the learning model 16 by inputting, as input data to the learning model 16, the target processing quantity TWPH received in step S310 and the device information 10 acquired in step S320.

Then, in step S340, the output processing part 303 performs an output processing for outputting the support information 14 generated in step S330, and ends the series of information processing method shown in FIG. 22. In the above information processing method, step S310 corresponds to a target processing quantity reception process, step S320 corresponds to a device information acquisition process, step S330 corresponds to a support information generation process, and step S340 corresponds to an output processing process.

As described above, according to the information processing device 3B and the information processing method according to this embodiment, the support information generation part 302B generates the support information 14 including the recipe available time TRPW that is available for the substrate processing performed according to the recipe information 13, by inputting, to the learning model 16, the target processing quantity TWPH of substrates per unit time and the device information 10 including the transport processing information 11 defining the action state of the transport processing. Thus, when setting the recipe information 13, since the recipe available time TRPW that is available for the substrate processing can be identified in advance, the setting of the recipe information 13 can be appropriately supported.

### Other Embodiments

The disclosure is not limited to the embodiments described above and may be implemented with various changes within the scope without departing from the spirit of the disclosure. All of such changes are included in the technical concept of the disclosure.

In the above embodiments, although the substrate processing apparatus 2 and the information processing devices 3A and 3B have been described as being composed of separate apparatuses, they may also be composed of one apparatus. For example, the information processing devices 3A and 3B may be incorporated into the control unit 25 of the substrate processing apparatus 2. Further, the machine learning device 5 may be incorporated into the control unit 25 of the substrate processing apparatus 2.

In the above embodiments, although the substrate processing apparatus 2 has been described as one that performs a chemical-mechanical polishing processing as the polishing processing, the substrate processing apparatus 2 may also perform a physical-mechanical polishing processing instead of the chemical-mechanical polishing processing. Further, although the substrate processing apparatus 2 has been described as one that performs a polishing processing and a finishing processing on the wafer W as the substrate processing, the substrate processing apparatus 2 may also perform any of the polishing processing and the finishing processing, and may perform other substrate processings in addition to or instead of the polishing processing and the finishing processing.

In the above embodiments, it has been described that the substrate processing apparatus 2 includes each substrate processing unit (polishing unit and finishing unit) and each transport processing unit, as shown in FIG. 2. However, as the configuration of the substrate processing apparatus 2, the quantity, arrangement, upstream-downstream relationship, parallel relationship, and serial relationship of each substrate processing unit and each transport processing unit are not limited to the example in FIG. 2 and may be appropriately changed. For example, the quantity of the polishing unit may be one or plural, and the quantity of the finishing unit may be one or plural. Further, as the quantity of the transport processing unit, the quantity of the supply discharge robot may be one or plural, the quantity of the first to third transport robots may be one or plural, and the quantity of the transfer robot may be one or plural. Further, the positions to hand over the wafer W, the positions to cause the wafer W is temporarily stand by, etc. between each substrate processing unit and each transport processing unit may be appropriately changed, and the quantities of these positions may be increased as appropriate. In such a case, the calculation method of the recipe available time TRPW in the support information generation part 302A may be changed according to the configuration of each substrate processing unit and each transport processing unit. Further, the data structure of the input data and the output data in the learning data 15 and the learning model 16 may be changed according to the configuration of each processing unit.

In the above embodiments, although it has been described that a neural network is adopted as the learning model that realizes machine learning performed by the machine learning part 305, other machine learning models may be also adopted. Examples of other machine learning models include a tree type such as decision trees and regression trees, ensemble learning such as bagging and boosting, a neural network type (including deep learning) such as recurrent neural networks, convolutional neural networks, and LSTM, a clustering type such as hierarchical clustering, non-hierarchical clustering, a k-nearest neighbor algorithm, and a k-means clustering, multivariate analysis such as principal component analysis, factor analysis, and logistic regression, support vector machine, etc. Further, the machine learning algorithm executed by the machine learning part 305 may also adopt reinforcement learning instead of supervised learning.

### Machine Learning Program and Information Processing Program

The disclosure may also be provided in the form of a program (information processing program) for causing the computer 900 to function as each part included in the information processing devices 3A and 3B, or a program (information processing program) for causing the computer 900 to perform each process included in the information processing method according to the above embodiments. Further, the disclosure may also be provided in the form of a program (machine learning program) for causing the computer 900 to function as each part included in the machine learning device 5, or a program (machine learning program) for causing the computer 900 to perform each process included in the machine learning method.

### Inference Device, Inference Method, and Inference Program

The disclosure is not only provided in the form of the information processing devices 3A and 3B (information processing method or information processing program) according to the above embodiments, but may also be provided in the form of an inference device (inference method or inference program) that supports the operation of the substrate processing apparatus. In that case, a memory and a processor may be included as the inference device (inference method or inference program), and this processor may perform a series of processings. The series of processings include a target processing quantity reception processing (target processing quantity reception process) of receiving the target processing quantity TWPH of substrates per unit time, a device information acquisition processing (device information acquisition process) of acquiring the device information 10 including the transport processing information 11, and an inference processing (inference process) in which, upon reception of the target processing quantity TWPH in the target processing quantity reception processing and acquisition of the device information 10 in the device information acquisition processing, the support information 14 including the recipe available time TRPW is inferred based on the target processing quantity TWPH and the device information 10.

By providing in the form of the inference device (inference method or inference program), it becomes possible to apply to various devices simply compared to the case of implementing an information processing device. It is readily understandable to those skilled in the art that when the inference device (inference method or inference program) infers the support information, an inference technique executed by the support information generation part may be applicable using a learned learning model generated by the machine learning device and the machine learning method according to the above embodiments.

What is claimed is:

1. An information processing device supporting an operation of a substrate processing apparatus, the substrate processing apparatus comprising: a substrate processing unit that performs a substrate processing on a substrate according to recipe information indicating a processing content of the substrate processing; and a transport processing unit that performs a transport processing of transporting the substrate before the substrate processing and after the substrate processing,
the information processing device comprising:
a target processing quantity reception part that receives a target processing quantity of the substrate per unit time of a time when a processing action repeating the substrate processing and the transport processing on a plurality of substrates is performed in the substrate processing apparatus;
a device information acquisition part that acquires device information comprising transport processing information which defines an action state of the transport processing of the time when the processing action is performed; and
a support information generation part that generates support information comprising a recipe available time which is available for the substrate processing performed according to the recipe information, based on the target processing quantity received by the target processing quantity reception part and the device information acquired by the device information acquisition part.

2. The information processing device according to claim 1, wherein
the transport processing unit is composed of a plurality of transport processing units in which a transport route of a time when transporting the substrate in the transport processing is capable of being selected, and
the transport processing information comprises:
the transport route selected when the processing action is performed; and
a unit transport processing time required for each of the transport processings performed by the plurality of transport processing units when the processing action is performed.

3. The information processing device according to claim 1, wherein
the device information comprises device setting information that defines an action content of the substrate processing apparatus of the time when the processing action is performed, by setting a setting value respectively for each of a plurality of device setting items.

4. The information processing device according to claim 1, wherein
the support information generation part
calculates a unit transport time required for the transport processing per substrate based on the transport processing information, and
calculates the recipe available time by subtracting the unit transport time from a unit processing time per substrate converted from the target processing quantity.

5. The information processing device according to claim 2, wherein
the support information generation part
calculates a unit transport time required for the transport processing per substrate by adding up the unit transport processing time according to the transport route, and
calculates the recipe available time by subtracting the unit transport time from a unit processing time per substrate converted from the target processing quantity.

6. The information processing device according to claim 3, wherein
the support information generation part
calculates a unit transport time required for the transport processing per substrate based on the transport processing information,
calculates, based on the device setting information, a unit overhead time required for a preparation action per substrate of a time when the preparation action is performed before the substrate processing and after the substrate processing on the substrate held in the substrate processing unit, and
calculates the recipe available time by subtracting the unit transport time and the unit overhead time from a unit processing time per substrate converted from the target processing quantity.

7. The information processing device according to claim 1, wherein
the support information generation part generates the support information for the target processing quantity and the device information by inputting the target processing quantity received by the target processing quantity reception part and the device information acquired by the device information acquisition part, to a learning model that has been caused to learn a correlation of the target processing quantity and the device information with the support information by machine learning.

8. An inference device comprising a memory and a processor and supporting an operation of a substrate processing apparatus, the substrate processing apparatus comprising: a substrate processing unit that performs a substrate processing on a substrate according to recipe information indicating a processing content of the substrate processing; and a transport processing unit that performs a transport processing of transporting the substrate before the substrate processing and after the substrate processing,
the inference device performing:
a target processing quantity reception processing of receiving a target processing quantity of the substrate per unit time of a time when a processing action repeating the substrate processing and the transport processing on a plurality of substrates is performed in the substrate processing apparatus;
a device information acquisition processing of acquiring device information comprising transport processing information that defines an action state of the transport processing of the time when the processing action is performed; and
an inference processing of inferring, based on the target processing quantity and the device information, support information comprising a recipe available time that is available for the substrate processing performed according to the recipe information, upon reception of the target processing quantity in the target processing quantity reception processing and acquisition of the device information in the device information acquisition processing.

9. A machine learning device generating a learning model for supporting an operation of a substrate processing apparatus, the substrate processing apparatus comprising: a substrate processing unit that performs a substrate processing on a substrate according to recipe information indicating a processing content of the substrate processing; and a transport processing unit that performs a transport processing of transporting the substrate before the substrate processing and after the substrate processing,
the machine learning device comprising:
a learning data storage part that stores a plurality of sets of learning data composed of an input data and an output data;
a machine learning part that causes the learning model to learn a correlation between the input data and the output data by inputting the plurality of sets of learning data to the learning model; and
a learned model storage part that stores the learning model which has been caused to learn the correlation by the machine learning part, wherein
the input data is
a target processing quantity of the substrate per unit time of a time when a processing action repeating the substrate processing and the transport processing on a plurality of substrates is performed in the substrate processing apparatus; and
device information comprising transport processing information that defines an action state of the transport processing of the time when the processing action is performed, and
the output data is support information comprising a recipe available time that is available for the substrate processing performed according to the recipe information.
